(19) United States
(12) Patent Application Publication
(10) Pub. No.: US 2009/0075214 A1
(43) Pub. Date: Mar. 19, 2009

(54) MANUFACTURING METHOD OF LIGHT EMITTING DEVICE, AND EVAPORATION DONOR SUBSTRATE

(75) Inventors: Yoshiharu HIRAKATA, Ebina (JP); Hisao IKEDA, Isehara (JP); Kohei YOKOYAMA, Isehara (JP); Yosuke SATO, Atsugi (JP)

Correspondence Address: ERIC ROBINSON, PMB 955, 21010 SOUTHBANK ST., POTOMAC FALLS, VA, 20165, US

(73) Assignee: SEMICONDUCTOR ENERGY LABORATORY CO., LTD., Kanagawa-ken (JP)

(21) Appl. No.: 12/203,424

(22) Filed: Sep. 3, 2008

(30) Foreign Application Priority Data
Sep. 13, 2007 (JP) 2007-237493

(51) Int. Cl. G03F 7/00

(52) U.S. Cl. 430/319

(57) ABSTRACT

An object is to provide a manufacturing method of a light emitting device, by which manufacturing costs in manufacturing a flat panel display can be reduced. A first substrate provided with a reflective layer having an opening over a first surface, and provided with a light absorption layer and an evaporation material over a second surface facing the first surface is used. Then, in a state where the second surface of the first substrate is disposed close to a first surface of a second substrate, light irradiation is performed from the first surface side of the first substrate. The irradiation light is absorbed by a portion of the light absorption layer overlapping with the opening in the reflective layer, thereby heating the evaporation material. The heated evaporation material is attached to the first surface of the second substrate.

### BACKGROUND OF THE INVENTION

1. Field of the Invention

The present invention relates to a light emitting device and a manufacturing method of the light emitting device. The present invention also relates to an evaporation donor substrate used for deposition of a material.

2. Description of the Related Art

Organic compounds can take various structures compared with inorganic compounds, and it is possible to synthesize a material having various functions by appropriate molecular design of an organic compound. Owing to these advantages, photo electronics and electronics which employ a functional organic material have been attracting attention in recent years.

A solar cell, a light emitting element, an organic transistor, and the like can be given as examples of electronics devices using an organic compound as a functional organic material. These devices take advantage of electrical properties and optical properties of the organic compound. Among them, in particular, a light emitting element has been making remarkable development.

It is said that a light emission mechanism of a light emitting element emits light as follows: when a voltage is applied between a pair of electrodes with an EL layer interposed therebetween, electrons injected from a cathode and holes injected from an anode are recombined at emission centers in the EL layer to form molecular excitons, and energy is released when the molecular excitons relax to the ground state. As excited states, a singlet excited state and a triplet excited state are known, and light emission is considered to be possible through either of these excited states.

An EL layer included in a light emitting element has at least a light emitting layer. The EL layer can also have a stacked-layer structure including a hole injecting layer, a hole transporting layer, an electron transporting layer, an electron injecting layer, and/or the like, in addition to the light emitting layer.

EL materials for forming EL layers are broadly classified into a low molecular (monomer) material and a high molecular (polymer) material. In general, a low molecular material is often deposited using an evaporation apparatus and a high molecular material using an inkjet method or the like. A conventional evaporation apparatus, in which a substrate is mounted in a substrate holder, has a crucible (or an evaporation boat) containing an EL material, i.e., an evaporation material, a heater for heating the EL material in the crucible, and a shutter for preventing the subliming EL material from being scattered. Then, the EL material heated by the heater is sublimed and deposited onto the substrate. In order to achieve uniform deposition, a deposition target substrate needs to be rotated and the distance between the substrate and the crucible needs to be about 1 m even when the substrate has a size of 300 mm×360 mm.

When this method is employed to manufacture a full-color flat panel display using emission colors of red, green, and blue, a metal mask is provided in contact with the substrate between the substrate and an evaporation source and selective coloring can be achieved through this mask. However, this method does not provide very high deposition accuracy and thus requires that the distance between pixels be designed to be large and the width of a partition (bank) formed of an insulator between pixels be large. Therefore, application of the method to a high-definition display device is difficult.

Demands for higher definition, higher aperture ratio, and higher reliability of a full-color flat panel display using emission colors of red, green, and blue have been increasing. Such demands are major issues in advancing miniaturization of each display pixel pitch which is associated with improvement in definition (an increase in the number of pixels) and a reduction in size of a light emitting device. At the same time, demands for higher productivity and lower cost have also been increasing.

Thus, a method for forming an EL layer of a light emitting element through laser thermal transfer has been proposed (see Reference 1: Japanese Published Patent Application No. 2006-309995). Reference 1 discloses a transfer substrate which has a photothermal conversion layer including a low-reflective layer and a high-reflective layer and also a transfer layer over a supporting substrate. Irradiation of such a transfer substrate with laser light allows the transfer layer to be transferred to an element-forming substrate.

### SUMMARY OF THE INVENTION

However, the high-reflective layer and the low-reflective layer of the transfer substrate of Reference 1 are stacked on one side of the substrate. Therefore, even with the use of the high-reflective layer, a certain degree of heat absorption is conceivable. Thus, when the power of laser light is large, not only a portion of the transfer layer over the low-reflective layer but also a portion of the transfer layer over the high-reflective layer may be transferred.

In a configuration shown in FIG. 3 of Reference 1, as also described in paragraph [0041], no spacing is allowed between the low-reflective layer and the high-reflective layer and highly precise patterning is necessary.

In a configuration shown in FIG. 7 of Reference 1, the low-reflective layer is patterned; the high-reflective layer is then formed over the entire surface; and the transfer layer is then formed. In this configuration, heat from the low-reflective layer which is heated by absorbing laser light is transferred to the transfer layer through the high-reflective layer. Thus, not only a desired portion of the transfer layer but also a portion of the transfer layer around the desired portion may be transferred.

Therefore, it is an object of the present invention to provide a manufacturing method of a light emitting device, by which manufacturing costs in manufacturing a flat panel display using emission colors of red, green, and blue can be reduced through an increase in use efficiency of an EL material and by which high uniformity in deposition of a layer containing an evaporation material such as an EL layer and high throughput can be achieved.

It is another object of the present invention to provide a manufacturing method of a light emitting device, and an evaporation donor substrate, with which miniaturization of each display pixel pitch which is associated with improvement in definition (an increase in the number of pixels) and a reduction in size of a light emitting device can be advanced.

In the present invention, a first substrate provided with a reflective layer having an opening over a first surface and provided with a light absorption layer over a second surface facing the first surface is used. An evaporation material is attached to the second surface side of the first substrate. Then, in a state where the second surface of the first substrate is disposed close to a first surface of a second substrate, light irradiation is performed from the first surface side of the first substrate. The irradiation light is absorbed by a portion of the light absorption layer overlapping with the opening in the reflective layer, thereby heating the evaporation material. The heated evaporation material is attached to the first surface of the second substrate.

Note that, in this specification, attachment refers to sublimation of at least a part of a material and deposition thereof onto a deposition target substrate.

One aspect of the present invention is a manufacturing method of a light emitting device, including the steps of: attaching an evaporation material to a second surface side of a first substrate, which is provided with a reflective layer having an opening over a first surface and provided with a light absorption layer over the second surface facing the first surface; and performing light irradiation from the first surface side of the first substrate in a state where the second surface of the first substrate is disposed close to a first surface of a second substrate and making the light absorbed by a portion of the light absorption layer overlapping with the opening in the reflective layer to heat the evaporation material and to attach the evaporation material to the first surface side of the second substrate.

Another aspect of the present invention is a manufacturing method of a light emitting device, including the steps of: forming a reflective layer having an opening over a first surface of a first substrate; forming a light absorption layer over a second surface facing the first surface; attaching an evaporation material to the second surface side of the first substrate; and performing light irradiation from the first surface side of the first substrate in a state where the second surface of the first substrate is disposed close to a first surface of a second substrate and making the irradiation light absorbed by a portion of the light absorption layer overlapping with the opening in the reflective layer to heat the evaporation material and to attach the evaporation material to the first surface side of the second substrate.

Another aspect of the present invention is a manufacturing method of a light emitting device, using a first substrate provided with a reflective layer having an opening over a first surface and provided with a light absorption layer over a second surface facing the first surface, and a second substrate provided with a first electrode over a first surface. The manufacturing method includes the steps of: attaching an evaporation material to the second surface side of the first substrate; performing light irradiation from the first surface side of the first substrate in a state where the second surface of the first substrate is disposed close to the first surface of the second substrate and making the irradiation light absorbed by a portion of the light absorption layer overlapping with the opening in the reflective layer to heat the evaporation material and to attach the evaporation material to the first surface of the second substrate; and forming a second electrode over the first surface of the second substrate.

Another aspect of the present invention is a manufacturing method of a light emitting device, including the steps of: forming a reflective layer having an opening over a first surface of a first substrate; forming a light absorption layer over a second surface facing the first surface; attaching an evaporation material to the second surface side of the first substrate; forming a first electrode over a first surface of a second substrate; performing light irradiation from the first surface side of the first substrate in a state where the second surface of the first substrate is disposed close to the first surface of the second substrate and making the irradiation light absorbed by a portion of the light absorption layer overlapping with the opening in the reflective layer to heat the evaporation material and to attach the evaporation material to the first surface of the second substrate; and forming a second electrode over the first surface of the second substrate.

In each of the above aspects, the light absorption layer may be formed over the entire first surface of the first substrate or may be formed in an island shape to overlap with the opening in the reflective layer. Formation of the light absorption layer in an island shape can prevent heat from being conducted in the light absorption layer, which enables a second layer containing the evaporation material to be patterned more precisely.

In each of the above aspects, it is preferable that the irradiation light be infrared light. The use of infrared light enables the light absorption layer to be heated efficiently.

In each of the above aspects, it is preferable that the reflective layer have a reflectance of 85% or more for the irradiation light. It is also preferable that the light absorption layer have a reflectance of 60% or less for the irradiation light. In this manner, it is preferable that a difference in reflectance between the reflective layer and the light absorption layer be 25% or more.

In each of the above aspects, it is preferable that the thickness of the reflective layer be 100 nm or more. It is also preferable that the thickness of the light absorption layer be 200 nm to 600 nm.

In each of the above aspects, it is preferable that the reflective layer contain aluminum, silver, gold, platinum, copper, an alloy containing aluminum, an alloy containing silver, or the like.

In each of the above aspects, tantalum nitride, titanium, carbon, or the like can be used for the light absorption layer.

In each of the above aspects, it is preferable that the evaporation material be attached to the second surface side of the first substrate by a wet method. Because material use efficiency in a wet method is high, the use of a wet method can reduce manufacturing cost of a light emitting device.

In each of the above aspects, it is preferable that an organic compound be used as the evaporation material. Because many organic compounds have a lower evaporation temperature than inorganic compounds, organic compounds are suitable for the manufacturing method of a light emitting device of the present invention. For example, a light emitting material or a carrier transporting material can be used.

Another aspect of the present invention is an evaporation donor substrate having a first surface, which is provided with a reflective layer having an opening, and a second surface, which faces the first surface and is provided with a light absorption layer.

In the above aspect, the light absorption layer may be formed over the entire first surface of the evaporation donor substrate or may be formed in an island shape to overlap with the opening in the reflective layer. Formation of the light absorption layer in an island shape can prevent heat from being conducted in the light absorption layer, which enables a second layer containing an evaporation material to be patterned more precisely.

In the above aspect, it is preferable that the evaporation material be attached onto the light absorption layer. The evaporation donor substrate to which the evaporation material is attached can be used for evaporation without any change.

It is also preferable that an organic compound be used as the evaporation material. Because many organic compounds have a lower evaporation temperature than inorganic compounds, organic compounds can be easily evaporated by light irradiation. For example, a light emitting material or a carrier transporting material can be used.

In the above aspect, it is preferable that the thickness of the reflective layer be 100 nm or more.

In the above aspect, it is preferable that the reflective layer contain aluminum, silver, gold, platinum, copper, an alloy containing aluminum, an alloy containing silver, or the like.

In the above aspect, it is preferable that the thickness of the light absorption layer be 200 nm to 600 nm.

In the above aspect, it is preferable that the light absorption layer contain tantalum nitride, titanium, carbon, or the like.

In the above aspect, it is preferable that the evaporation material be attached to the second surface side of the first substrate by a wet method.

Application of the present invention makes it possible to easily form a layer containing an evaporation material, which is included in a light emitting element, and to easily manufacture a light emitting device including the light emitting element.

Application of the present invention also makes it possible to form a flat even film. In addition, the present invention increases the precision in patterning a layer containing an evaporation material into a desired shape. Accordingly, a light emitting device having excellent properties can be obtained.

The use of the evaporation donor substrate of the present invention makes it possible to form a film in a desired shape with high precision.

### BRIEF DESCRIPTION OF THE DRAWINGS

FIGS. 1A to 1C are schematic diagrams each showing a cross section in a deposition process of the present invention.

FIGS. 2A to 2C are schematic diagrams each showing a cross section in a deposition process of the present invention.

FIGS. 3A and 3B are diagrams each showing an example of a light emitting element.

FIGS. 4A and 4B are diagrams each showing an example of a light emitting element.

FIGS. 5A to 5C are a top view and cross-sectional views of an example of a passive-matrix light emitting device.

FIG. 6 is a perspective view of an example of a passive-matrix light emitting device.

FIG. 7 is a top view of an example of a passive-matrix light emitting device.

FIGS. 8A and 8B are a top view and a cross-sectional view of an active-matrix light emitting device, respectively.

FIGS. 9A and 9B are diagrams each showing an example of a deposition apparatus.

FIGS. 10A and 10B are diagrams each showing an example of a deposition apparatus.

FIGS. 11A to 11E are diagrams each showing an example of an electronic device.

FIGS. 12A to 12C are schematic diagrams each showing a cross section in a deposition process of the present invention.

FIGS. 13A and 13B are diagrams illustrating a deposition process of the present invention.

FIGS. 14A and 14B are diagrams illustrating a deposition process of the present invention.

FIG. 15 is a diagram showing an example of a deposition apparatus.

FIGS. 16A and 16B are diagrams showing an example of a deposition apparatus.

FIG. 17 is a diagram showing an example of a deposition apparatus.

FIG. 18 is a diagram showing reflectances of metal films.

FIGS. 19A to 19C are schematic diagrams each showing a cross section in a deposition process of the present invention.

FIGS. 20A to 20C are schematic diagrams each showing a cross section in a deposition process of the present invention.

FIG. 21 is a diagram showing reflectances of aluminum films.

FIGS. 22A and 22B are diagrams showing reflectances and transmittances of titanium films, respectively.

FIG. 23 is a diagram showing absorptances of titanium films.

### DETAILED DESCRIPTION OF THE INVENTION

Embodiment modes and embodiments of the present invention will be described with reference to the drawings. However, the present invention is not limited to the following description and it is easily understood by those skilled in the art that the mode and detail of the present invention can be changed in various ways without departing from the spirit and scope thereof. Therefore, the present invention is not interpreted as being limited to the following description of the embodiment modes and embodiments. Note that, in the configurations of the present invention described below, the same reference numeral may be commonly used to denote the same component in different diagrams.

### Embodiment Mode 1

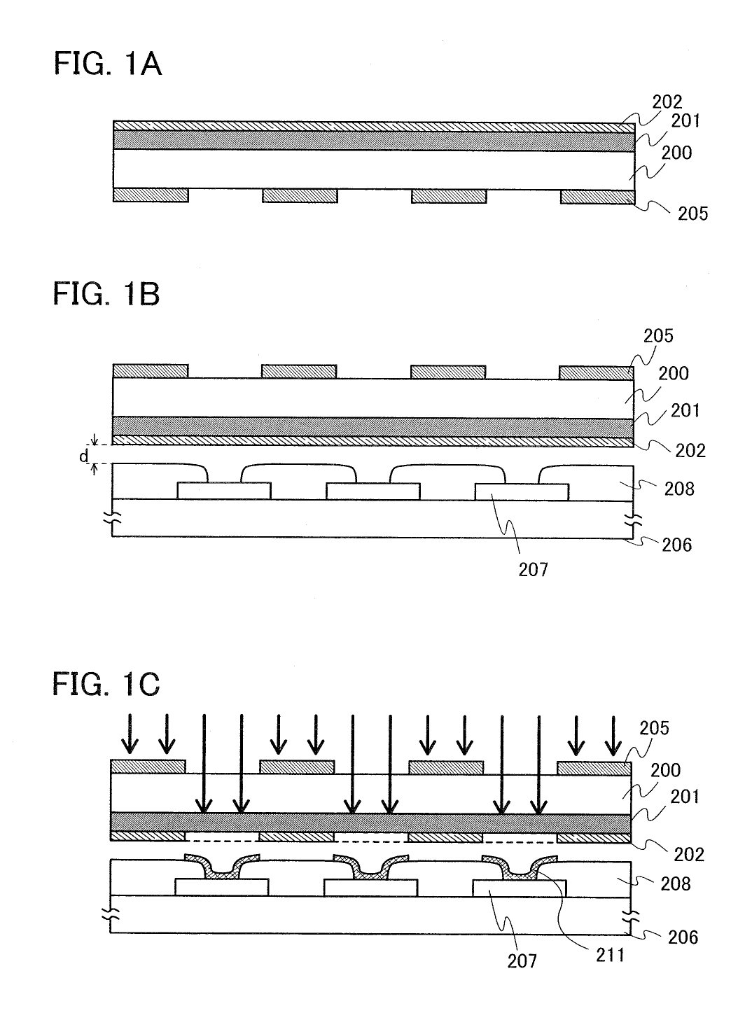

A manufacturing method of a light emitting device, and an evaporation donor substrate of the present invention are described with reference to FIGS. 1A to 1C.

FIG. 1A shows an evaporation donor substrate of the present invention. In FIG. 1A, a reflective layer 205 is formed on a first surface side of a first substrate 200 that is a supporting substrate. The reflective layer 205 has an opening. On a second surface side facing the first surface of the first substrate 200, a light absorption layer 201 is formed. In FIGS. 1A to 1C, the light absorption layer 201 is formed over the entire second surface of the first substrate 200. In addition, an evaporation material is attached onto the light absorption layer 201. In FIG. 1A, a first layer 202 containing the evaporation material is formed.

The first substrate 200 is a supporting substrate for the reflective layer, the light absorption layer, and the like and transmits irradiation light used for evaporating the first layer containing the evaporation material in a manufacturing process of a light emitting device. Therefore, it is preferable that the first substrate 200 have high light transmittance. Specifically, when lamp light or laser light is used to evaporate the first layer containing the evaporation material, it is preferable that a substrate which transmits the light be used as the first substrate 200. It is also preferable that the first substrate 200 be formed of a material having low thermal conductivity. Even if the reflective layer 205 formed over the first surface of the first substrate 200 is heated, the first substrate 200 having low thermal conductivity can suppress heat transfer to the second surface of the first substrate 200 and can prevent the first layer 202 containing the evaporation material from being heated and evaporated. As the first substrate 200, for example, a glass substrate, a quartz substrate, a plastic substrate containing an inorganic material, or the like can be used.

The reflective layer 205 reflects irradiation light used for evaporating the first layer containing the evaporation material in a manufacturing process of a light emitting device. The reflective layer preferably has a reflectance of 85% or more, more preferably, a reflectance of 90% or more for the irradiation light. Therefore, it is preferable that the reflective layer be formed of a material having high reflectance for the irradiation light. For example, silver, gold, platinum, copper, an alloy containing aluminum, an alloy containing silver, or the like can be used. In particular, an aluminum-titanium alloy, an aluminum-neodymium alloy, or a silver-neodymium alloy has high reflectance for light in an infrared region (at a wavelength of 800 nm or more) and is thus suitably used for the reflective layer. As described above, depending on the wavelength of irradiation light used for evaporating the first layer containing the evaporation material, the kind of suitable material for the reflective layer 205 varies.

It is more preferable that the reflective layer be formed of a material having low thermal conductivity. The use of a material having low thermal conductivity enables a second layer containing the evaporation material to be patterned precisely. An example of a material having low thermal conductivity is platinum or like.

The reflective layer is not limited to a single layer and may include a plurality of layers. For example, a stack of a film formed of a material having high reflectance and a film formed of a material having low thermal conductivity may be used as the reflective layer. In the manufacturing method of a light emitting device described in this embodiment mode, the reflective layer is formed on the first surface side of the substrate and the light absorption layer is formed on the second surface side facing the first surface of the substrate. That is, the reflective layer and the light absorption layer are not formed on the same side of the substrate; therefore, the reflective layer and the light absorption layer do not need to have the same thickness. Accordingly, the degree of design freedom for thickness or stacked structure of the reflective layer can be increased.

The reflective layer 205 can be formed using any of various kinds of methods. For example, the reflective layer 205 can be formed by a sputtering method, an electron beam evaporation method, a vacuum evaporation method, or the like. It is preferable that the thickness of the reflective layer be about 100 nm or more although it depends on a material. With a thickness of 100 nm or more, transmission of irradiation light through the reflective layer can be suppressed.

The opening can be formed in the reflective layer 205 by any of various kinds of methods but is preferably formed by dry etching. By use of dry etching, the opening has a sharper sidewall and a precise pattern can be formed.

The light absorption layer 201 absorbs irradiation light used for evaporating the first layer containing the evaporation material in a manufacturing process of a light emitting device. It is preferable the light absorption layer have low reflectance, low transmittance, and high absorptance for the irradiation light. Specifically, it is preferable that the light absorption layer have a reflectance of 60% or less for the irradiation light. In addition, it is preferable that the light absorption layer have an absorption of 40% or more for the irradiation light. Therefore, it is preferable that the light absorption layer be formed of a material having low reflectance and high absorptance for the irradiation light. It is also preferable that the light absorption layer be formed of a material having high heat resistance. For example, for light having a wavelength of 800 nm, molybdenum, tantalum nitride, titanium, tungsten, or the like is preferably used. For light having a wavelength of 1300 nm, tantalum nitride, titanium, or the like is preferably used. In this manner, depending on the wavelength of the irradiation light used for evaporating the first layer containing the evaporation material, the kind of suitable material for the light absorption layer 201 varies.

The light absorption layer 201 can be formed using any of various kinds of methods. For example, the light absorption layer 201 can be formed by a sputtering method using a target of molybdenum, tantalum, titanium, tungsten, an alloy thereof, or the like. In addition, the light absorption layer is not limited to a single layer and may include a plurality of layers. In the manufacturing method of a light emitting device described in this embodiment mode, the reflective layer is formed on the first surface side of the substrate and the light absorption layer is formed on the second surface side facing the first surface of the substrate. That is, the reflective layer and the light absorption layer are not formed on the same side of the substrate; therefore, the reflective layer and the light absorption layer do not need to have the same thickness. Accordingly, the degree of design freedom for thickness or stacked structure of the light absorption layer can be increased.

It is preferable that the light absorption layer have a thickness such that it does not transmit the irradiation light. It is preferable that the light absorption layer have a thickness of about 100 nm or more although it depends on a material. In particular, the light absorption layer 201 having a thickness of 200 nm to 600 nm can efficiently absorb the irradiation light and can generate heat. In addition, the light absorption layer having a thickness of 200 nm to 600 nm allows the second layer containing the evaporation material to be formed in a more precise pattern with high accuracy.

Note that the light absorption layer 201 may partially transmit the irradiation light as long as it generates heat to a sublimation temperature of the evaporation material contained in the first layer 202 containing the evaporation material. However, when the light absorption layer partially transmits the light, it is preferable that a material which does not decompose even when irradiated with light be used for the first layer 202 containing the evaporation material.

Note that the greater the difference in reflectance between the reflective layer and the light absorption layer is, the more preferable it is. Specifically, the difference in reflectance for the wavelength of the irradiation light is preferably 25% or more, more preferably, 30% or more.

The first layer 202 containing the evaporation material is transferred through sublimation. There are various kinds of materials as evaporation materials. The first layer 202 containing the evaporation material may contain plural kinds of materials. In addition, the first layer 202 containing the evaporation material may be a single layer or a stack of a plurality of layers. When a plurality of layers each containing an evaporation material are stacked, co-evaporation is possible. Note that it is preferable that a plurality of layers each containing an evaporation material be stacked so as to contain an evaporation material having low evaporation temperature on the first substrate side. Such a configuration allows a plurality of layers each containing an evaporation material to be efficiently sublimed and evaporated. Note that the term “evaporation temperature” in this specification refers to a temperature at which a material is sublimed. The term “decomposition temperature” refers to a temperature at which a change is caused by the action of heat in at least a part of a chemical formula that represents a material.

The first layer 202 containing the evaporation material is formed by any of various kinds of methods. For example, a dry method such as a vacuum evaporation method or a sputtering method can be used. Alternatively, a wet method such as a spin coating method, a spray coating method, an ink-jet method, a dip coating method, a casting method, a die coating method, a roll coating method, a blade coating method, a bar coating method, a gravure coating method, or a printing method can be used. In order to form the first layer 202 containing the evaporation material by a wet method, a desired evaporation material may be dissolved or dispersed in a solvent and a solution or a dispersion may be adjusted. There is no particular limitation on the solvent as long as an evaporation material can be dissolved or dispersed therein and the solvent does not react with the evaporation material. Examples of the solvent are as follows: halogen solvents such as chloroform, tetrachloromethane, dichloromethane, 1,2-dichloroethane, and chlorobenzene; ketone solvents such as acetone, methyl ethyl ketone, diethyl ketone, n-propyl methyl ketone, and cyclohexanone; aromatic solvents such as benzene, toluene, and xylene; ester solvents such as ethyl acetate, n-propyl acetate, n-butyl acetate, ethyl propionate, γ-butyrolactone, and diethyl carbonate; ether solvents such as tetrahydrofuran and dioxane; amide solvents such as dimethylformamide and dimethylacetamide; dimethyl sulfoxide; hexane; water; and the like. A mixture of plural kinds of these solvents may also be used. The use of a wet method makes it possible to increase material use efficiency and to reduce manufacturing cost of a light emitting device.

Note that the thickness and uniformity of a second layer 211 containing the evaporation material, which is formed in a later step over a second substrate 206 that is a deposition target substrate, depend on the first layer 202 containing the evaporation material which is formed over the first substrate that is a supporting substrate. Therefore, it is important to uniformly form the first layer containing the evaporation material. Note that the first layer containing the evaporation material does not necessarily need to be a uniform layer as long as the thickness and uniformity of the second layer containing the evaporation material are ensured. For example, the first layer containing the evaporation material may be formed in a minute island shape or may be formed in an uneven layer shape. Control of the thickness of the first layer containing the evaporation material facilitates control of the thickness of the second layer 211 containing the evaporation material which is formed over the second substrate 206 that is a deposition target substrate.

Note that various kinds of materials can be used as the evaporation materials regardless of whether they are organic compounds or inorganic compounds. Because many organic compounds have a lower evaporation temperature than inorganic compounds, organic compounds are easily evaporated by light irradiation and suitable for the manufacturing method of a light emitting device of the present invention. Examples of organic compounds include a light emitting material, a carrier transporting material, and the like used for a light emitting device. Examples of inorganic compounds include a metal oxide, a metal nitride, a metal halide, an elemental metal, and the like used for a carrier transporting layer, a carrier injecting layer, an electrode, and the like of a light emitting device.

Next, as shown in FIG. 1B, the second substrate 206 that is a deposition target substrate is disposed to face the surface of the first substrate 200 where the light absorption layer 201 and the first layer 202 containing the evaporation material are formed. The second substrate 206 is a deposition target substrate onto which a desired layer is deposited by evaporation treatment. Then, the first substrate 200 and the second substrate 206 are disposed close to each other so as to face each other in proximity; specifically, they are disposed close to each other so that the distance d between the surface of the first layer containing the evaporation material which is provided over the first substrate 200 and the second substrate 206 is 0 mm to 0.05 mm, preferably, 0 mm to 0.03 mm.

Note that the distance d is defined as a distance between the surface of the first layer 202 containing the evaporation material which is formed over the supporting substrate and the surface of the deposition target substrate. In the case where some layer (such as a conductive layer which functions as an electrode or an insulating layer which functions as a partition) is formed over the deposition target substrate, the distance d is defined as a distance between the surface of the first layer 202 containing the evaporation material over the supporting substrate and the surface of the layer formed over the deposition target substrate. Note that, in the case where the surface of the first layer containing the evaporation material which is formed over the supporting substrate or the surface of the layer formed over the deposition target substrate is uneven, the distance d is defined as the shortest distance between the surface of the first layer 202 containing the evaporation material over the supporting substrate and the outermost surface of the layer formed over the deposition target substrate.

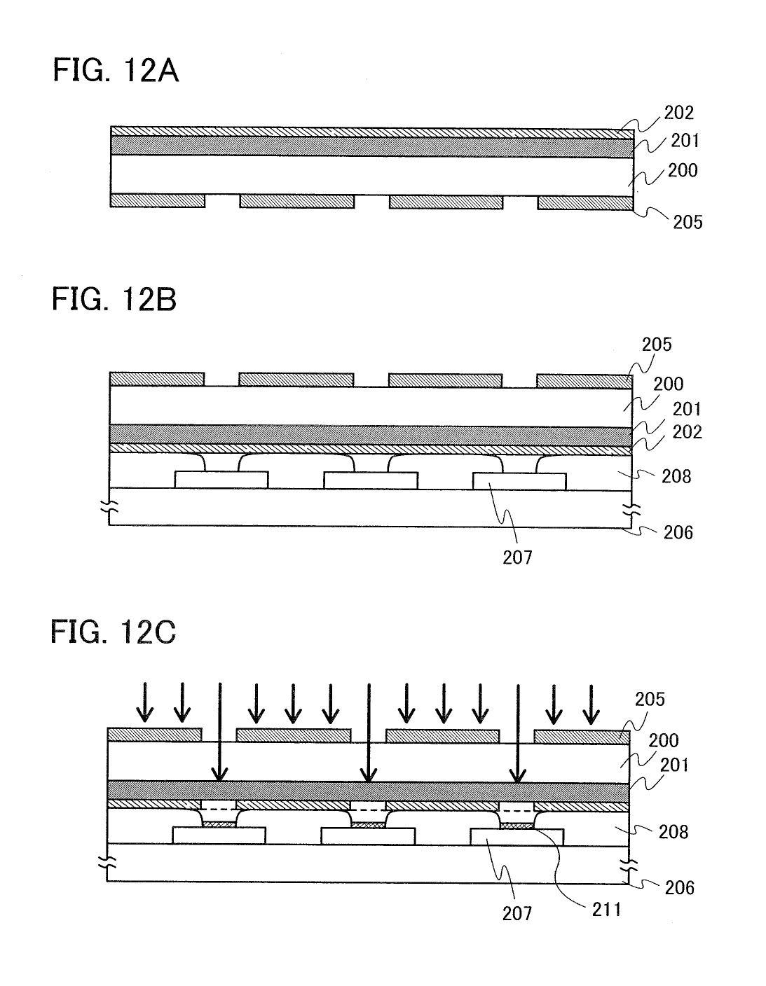

FIGS. 12A to 12C show a case where the distance d is 0 mm, that is, the case where an insulator 208 formed over the second substrate 206 is in contact with the first layer 202 containing the evaporation material which is formed over the first substrate 200. When the distance d is short in this manner, material use efficiency can be improved. In addition, the precision of patterning of the layer formed over the deposition target substrate can be improved. Note that, in the case where the surface of the deposition target substrate is even, it is preferable that the distance d be greater than 0 mm. That is, it is preferable that the distance d between the second substrate 206 that is the deposition target substrate and the first substrate 200 that is the supporting substrate be greater than 0 mm. When the distance d is greater than 0 mm in the case where the surface of the deposition target substrate is even, direct heat transfer from an evaporation donor substrate to the deposition target substrate can be prevented.

In order to improve material use efficiency or to improve the precision of patterning, it is preferable that the distance between the first substrate and the second substrate be shorter. However, the present invention is not limited to this condition.

In FIGS. 1B and 1C, the second substrate 206 has first electrode layers 207. It is preferable that edge portions of the first electrode layers 207 be covered with the insulator 208. In this embodiment mode, the first electrode layer represents an electrode which serves as an anode or a cathode of a light emitting element.

Then, light irradiation is performed from the side of the first substrate 200 where the reflective layer 205 is formed. A region of the light absorption layer 201 which is irradiated with light generates heat, and the heat energy is used to sublime the evaporation material. The evaporation material sublimed is attached onto the first electrode layers, thereby forming the second layer 211 containing the evaporation material (FIG. 1C).

Any of various kinds of light sources can be used as a light source of the irradiation light.

Examples of light sources of laser light are as follows: a gas laser such as an Ar laser, a Kr laser, or an excimer laser; a laser using, as a medium, single crystal YAG, YVO₄, forsterite (Mg₂SiO₄), YAlO₃, or GdVO₄, or polycrystalline (ceramic) YAG Y₂O₃, YVO₄, YAlO₃, or GdVO₄ doped with one or more of Nd, Yb, Cr, Ti, Ho, Er, Tm, and Ta as a dopant; a glass laser; a ruby laser; an alexandrite laser; a Ti:sapphire laser; a copper vapor laser; a gold vapor laser; and a combination thereof. The use of a solid-state laser that uses a solid as a laser medium is advantageous in that a maintenance-free condition can be maintained for a long time and output is relatively stable.

Examples of light sources of light other than laser light are as follows: discharge lamps such as a flash lamp (e.g., a xenon flash lamp and a krypton flash lamp), a xenon lamp, and a metal halide lamp; and exothermic lamps such as a halogen lamp and a tungsten lamp.

Note that it is preferable that the irradiation light be infrared light (at a wavelength of 800 nm or more). The use of infrared light enables the light absorption layer 201 to be heated efficiently and the evaporation material to be sublimed efficiently.

A feature of the manufacturing method of a light emitting device of the present invention is to heat a light absorption layer not with radiation heat but with light from a light source. If radiation heat is used, not only the evaporation donor substrate but also the entire inside of a deposition chamber is heated. However, in the present invention, the light absorption layer is heated without using radiation heat; thus, heating of the entire inside of the deposition chamber can be suppressed. In order to prevent the entire first layer containing the evaporation material which is formed over an evaporation donor substrate from being heated and evaporated, the length of time for light irradiation is set to be relatively short. For example, in the case where a halogen lamp is used as a light source, the first layer containing the evaporation material can be evaporated by being held at 300° C. to 800° C. for about 7 seconds to 15 seconds. In the case where a flash lamp is used as a light source, the first layer containing the evaporation material can be evaporated by being irradiated with light for 0.1 msec to 10 msec to 300° C. to 800° C. A flash lamp is capable of repeatedly irradiating a large area with very high-intensity light in a short time (0.1 msec to 10 msec); thus, heating can be performed uniformly and efficiently regardless of the area of the first substrate. In addition, heating of the first substrate can also be controlled by a change in length of a light emitting period. Furthermore, a flash lamp has a long lifetime and consumes less power during a standby period for light emission; thus, it can suppress running cost.

It is preferable that deposition be performed in a reduced-pressure atmosphere. The reduced-pressure atmosphere can be obtained by evacuation of the deposition chamber with an evacuation unit to a vacuum of about 5×10⁻³ Pa or less, preferably, about 10⁻⁴ Pa to 10⁻⁶ Pa.

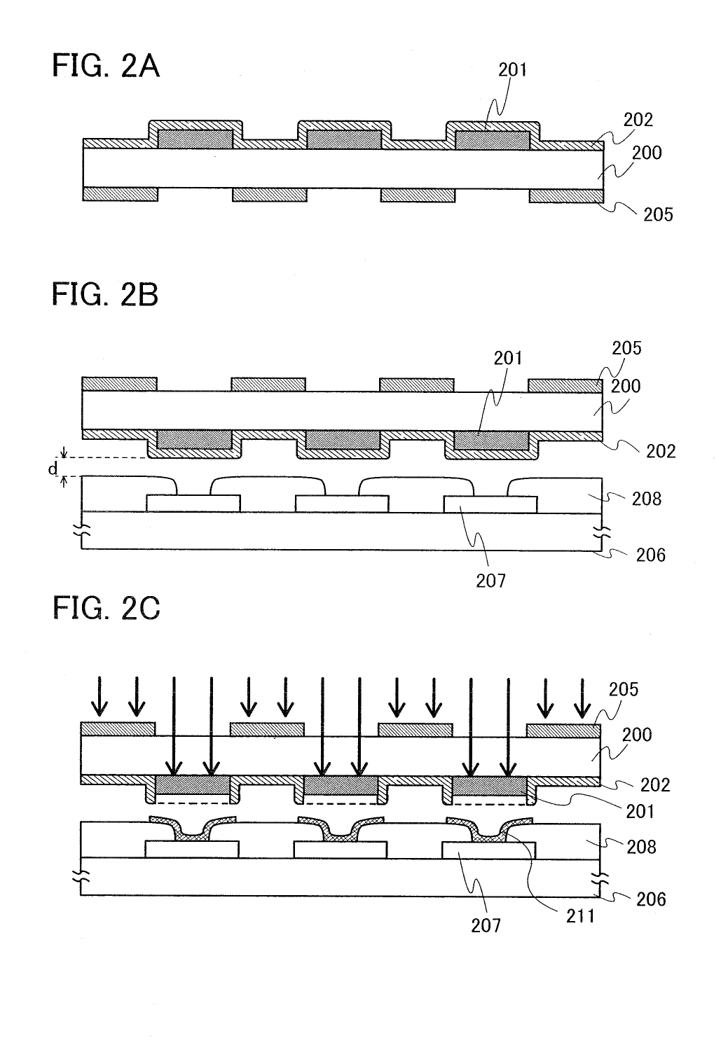

Note that although the light absorption layer 201 is formed over the entire surface of the first substrate 200 that is the supporting substrate in FIGS. 1A to 1C, the light absorption layer 201 may be patterned in an island shape as shown in FIGS. 2A to 2C. When the light absorption layer 201 is formed over the entire surface of the supporting substrate as shown in FIGS. 1A to 1C, there is no step in the first layer containing the evaporation material. Therefore, variations in thickness at the time of deposition can be suppressed. In addition, the light absorption layer is formed over the entire surface of the supporting substrate; thus, there is an advantage in that the thickness of the first layer containing the evaporation material is easily controlled. In the case where the light absorption layer 201 is patterned in an island shape as shown in FIGS. 2A to 2C, heat conduction in the light absorption layer can be prevented as compared to the case where the light absorption layer is formed over the entire surface. Therefore, the second layer containing the evaporation material can be patterned more precisely. That is, a high-definition light emitting device can be realized.

In the case where a light source of light having high directivity such as laser light is used as a light source, the light absorption layer 201 is irradiated with light having directivity through the opening in the reflective layer 205, and a portion of the first layer 202 containing the evaporation material which is irradiated with light is heated. That is, light which has passed through the opening in the reflective layer 205 is less likely to spread. Accordingly, a portion of the first layer containing the evaporation material which has the same or almost the same area as a region corresponding to the opening in the reflective layer 205 is evaporated. Because the irradiation light is less likely to spread, a structure may be employed in which the edge of the reflective layer is aligned with the edge of the light absorption layer 201 when seen from a light irradiation side as shown in FIGS. 2A to 2C.

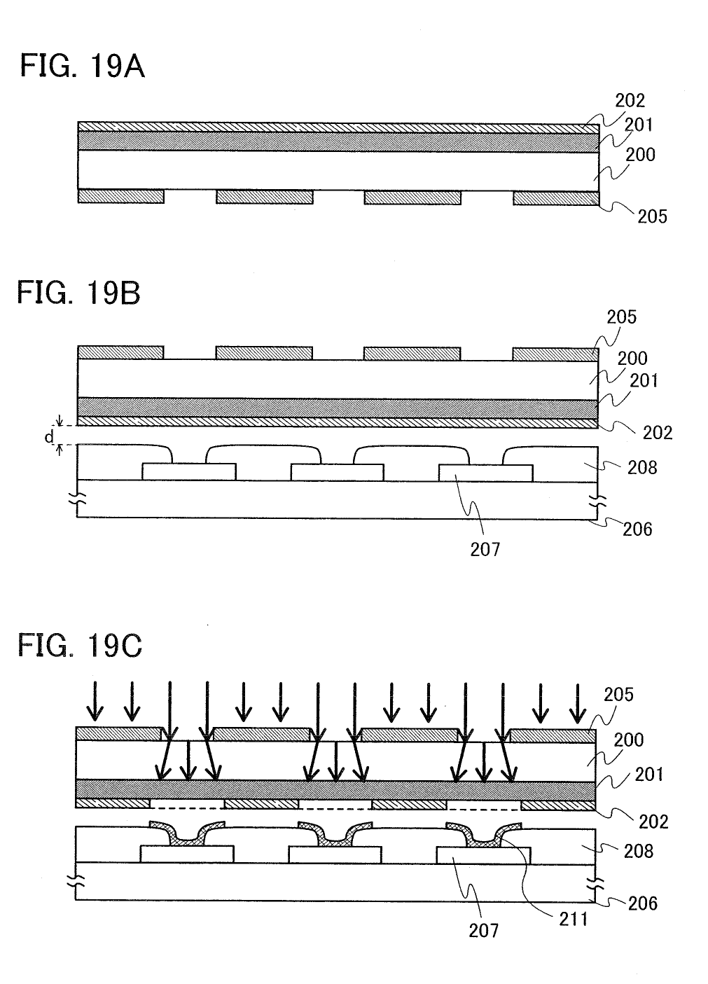

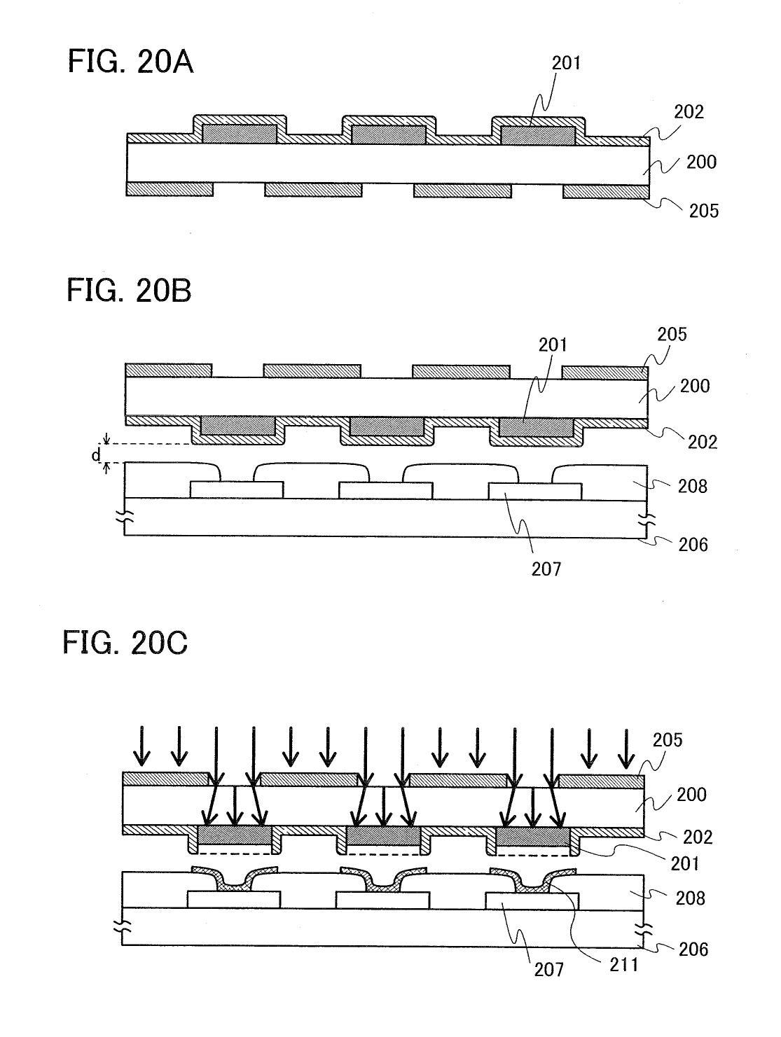

On the other hand, in the case where a light source of light having low directivity such as a flash lamp is used as a light source, a phenomenon occurs in which light which has passed through the opening in the reflective layer 205 spreads wider than the opening due to a difference in light incident angle. Accordingly, in consideration of spreading of the irradiation light, it is preferable that the opening in the reflective layer 205 be small. FIGS. 19A to 19C and FIGS. 20A to 20C show structures in each of which the opening in the reflective layer 205 is small. In FIGS. 19A to 19C and FIGS. 20A to 20C, light which has passed through the opening in the reflective layer 205 spreads as it is transmitted through the first substrate 200, and the light absorption layer 201 is irradiated with the light. Then, a portion of the first layer 202 containing the evaporation material, which has a larger area than a region corresponding to the opening in the reflective layer 205, is evaporated.

In this embodiment mode, the case where the second substrate that is the deposition target substrate is positioned below the first substrate that is the supporting substrate is shown. However, the present invention is not limited to this case. The disposition of the substrates can be appropriately determined.

In the deposition method which is applied to the light emitting device of the present invention, the thickness of the second layer containing the evaporation material which is deposited over the deposition target substrate through evaporation treatment can be controlled by control of the thickness of the first layer containing the evaporation material which is formed over the supporting substrate. That is, the first layer containing the evaporation material which is formed over the supporting substrate may be evaporated as it is; thus, a thickness monitor is not needed. Therefore, a user does not have to adjust the evaporation rate by use of a thickness monitor, and the deposition process can be fully automated. Accordingly, productivity can be increased.

By the deposition method of the present invention which is applied to a light emitting device, the evaporation material contained in the first layer containing the evaporation material can be uniformly sublimed. In the case where the first layer containing the evaporation material contains plural kinds of evaporation materials, the second layer containing the evaporation material, which contains the same evaporation materials at roughly the same weight ratio as those of the first layer containing the evaporation material, can be deposited over the deposition target substrate. As described above, in the deposition method of the present invention, in the case where deposition is performed using plural kinds of evaporation materials having different evaporation temperatures, unlike the case of co-evaporation, the evaporation rate of each evaporation material does not need to be controlled. Thus, without complicated control of the evaporation rate or the like, a desired layer containing different kinds of evaporation materials can be deposited easily and precisely.

Application of the present invention makes it possible to deposit a film having a less uneven surface and a uniform thickness. Application of the present invention facilitates patterning of a light emitting layer; thus, it also facilitates manufacture of a light emitting device. In addition, a precise pattern can be formed; thus, a high-definition light emitting device can be obtained. Furthermore, by application of the present invention, not only a laser but also a lamp heater or the like which is inexpensive but provides a large amount of heat can be used as a light source. Moreover, by use of a lamp heater or the like as a light source, deposition can be performed over a large area at a time; thus, cycle time can be shortened. Accordingly, manufacturing cost of a light emitting device can be reduced.

Moreover, by the deposition method of the present invention, a desired evaporation material can be deposited over the deposition target substrate without waste of the evaporation material. Thus, use efficiency of an evaporation material is increased, and costs can be reduced. Moreover, an evaporation material can be prevented from being attached to an inner wall of a deposition chamber, and thus maintenance of a deposition apparatus can be made easier.

Accordingly, application of the present invention makes it easy to deposit a desired layer containing different kinds of evaporation materials and makes it possible to increase productivity in manufacture of a light emitting device using the layer containing different kinds of evaporation materials, or the like.

The use of the evaporation donor substrate of the present invention makes it possible to deposit an evaporation material with high use efficiency and to reduce costs. Furthermore, the use of the evaporation donor substrate of the present invention makes it possible to form a film having a desired shape with high precision.

Note that this embodiment mode can be appropriately combined with any of the other embodiment modes described in this specification.

### Embodiment Mode 2

In this embodiment mode, a manufacturing method of a full-color display device by using the evaporation donor substrate used in Embodiment Mode 1 is described.

Embodiment Mode 1 shows the example in which deposition is performed onto each of the adjacent first electrode layers 207 in a single deposition step, whereas when a full-color display device is manufactured, light emitting layers which emit light of different colors are formed in different regions through a plurality of deposition steps.

A manufacturing example of a light emitting device capable of full color display is described below. In this embodiment mode, an example of a light emitting device using light emitting layers which emit light of three colors is described.

Three evaporation donor substrates each of which is the substrate shown in FIG. 1A are prepared. In each of the evaporation donor substrates, a layer containing a different kind of evaporation material is formed. Specifically, a first evaporation donor substrate provided with a material layer for a red light emitting layer, a second evaporation donor substrate provided with a material layer for a green light emitting layer, and a third evaporation donor substrate provided with a material layer for a blue light emitting layer are prepared.

In addition, one deposition target substrate provided with first electrode layers is prepared. Note that it is desirable to provide an insulator which covers an edge portion of each first electrode layer and serves as a partition so that the adjacent first electrode layers are not short-circuited. A region which serves as a light emitting region corresponds to part of the first electrode layer, that is, a region which is exposed without overlapping with the insulator.

Then, the deposition target substrate and the first evaporation donor substrate are superimposed on each other and aligned with each other. Thus, it is preferable that the deposition target substrate be provided with an alignment marker. It is also preferable that the first evaporation donor substrate be provided with an alignment marker. Note that, because the first evaporation donor substrate is provided with a light absorption layer, a portion of the light absorption layer over and near the alignment marker is desirably removed in advance. In addition, because the first evaporation donor substrate is provided with the material layer for the red light emitting layer, a portion of the material layer for the red light emitting layer over and near the alignment marker is desirably removed in advance.

Then, light irradiation is performed from the side of the first evaporation donor substrate on which the reflective layer is formed. The light absorption layer absorbs the irradiation light, thereby generating heat and making the material layer for the red light emitting layer that is in contact with the light absorption layer sublimed and deposited onto the first electrode layers provided over the deposition target substrate (first deposition). After the first deposition is completed, the first evaporation donor substrate is moved away from the deposition target substrate.

Next, the deposition target substrate and the second evaporation donor substrate are superimposed on each other and aligned with each other. The second evaporation donor substrate is provided with a light absorption layer in a position which is shifted by one pixel from that of the first evaporation donor substrate used in the first deposition.

Then, light irradiation is performed from the side of the second evaporation donor substrate on which the reflective layer is formed. The light absorption layer absorbs the irradiation light, thereby generating heat and making the material layer for the green light emitting layer that is in contact with the light absorption layer sublimed and deposited onto the first electrode layers provided over the deposition target substrate (second deposition). After the second deposition is completed, the second evaporation donor substrate is moved away from the deposition target substrate.

Next, the deposition target substrate and the third evaporation donor substrate are superimposed on each other and aligned with each other. The third evaporation donor substrate is provided with a light absorption layer in a position which is shifted by two pixels from that of the first evaporation donor substrate used in the first deposition.

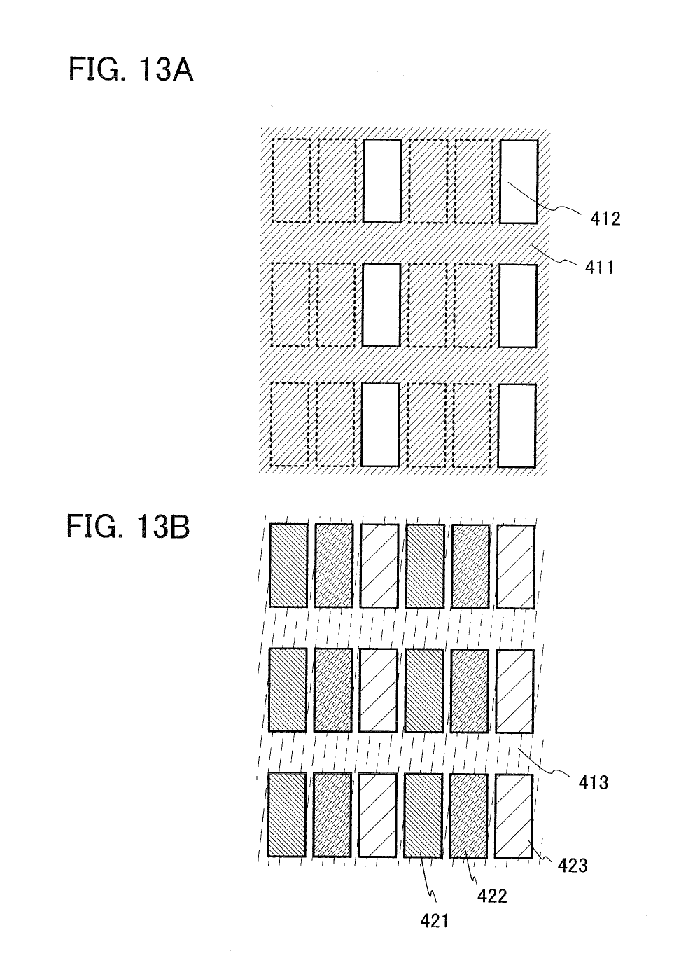

Then, light irradiation is performed from the side of the third evaporation donor substrate on which the reflective layer is formed, and third deposition is performed. A state right before the third deposition is performed corresponds to the top view of FIG. 13A. In FIG. 13A, a reflective layer 411 has openings 412. Light absorption layers are formed in regions corresponding to the openings 412. In regions of the deposition target substrate which correspond to the openings 412, the first electrode layers are exposed without being covered with an insulator 413. Note that first films (R) 421 deposited through the first deposition and second films (G) 422 deposited through the second deposition are located under regions indicated by dotted lines in FIG. 13A.

Then, third films (B) 423 are formed through the third deposition. The light absorption layer absorbs the irradiation light, thereby generating heat and making the material layer for the blue light emitting layer that is in contact with the light absorption layer sublimed and deposited onto the first electrode layers provided over the deposition target substrate (the third deposition). After the third deposition is completed, the third evaporation donor substrate is moved away from the deposition target substrate.

In this manner, the first films (R) 421, the second films (G) 422, and the third films (B) 423 are selectively formed at regular intervals. Then, a second electrode layer is formed over these films. Thus, light emitting elements are formed.

Through the above-described process, a full-color display device can be manufactured.

FIGS. 13A and 13B show the example in which the openings 412 in the reflective layer formed over the evaporation donor substrate each have a rectangular shape. However, the present invention is not particularly limited to this example and stripe openings may be employed. In the case where the stripe openings are employed, although deposition is also performed between light emitting regions which emit light of the same color, a film is formed over the insulator 413, and thus a portion which overlaps with the insulator 413 does not serve as a light emitting region.

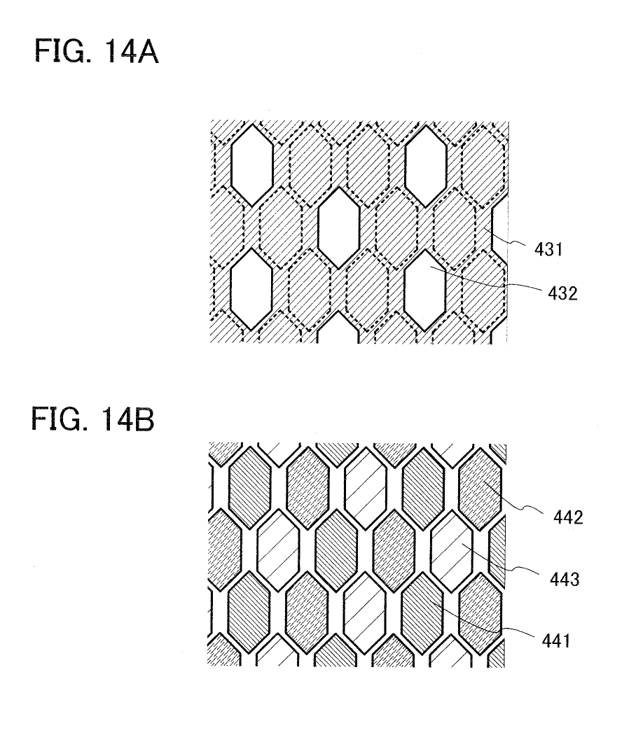

There is no particular limitation on the arrangement of the pixels. The shape of each pixel may be polygonal, for example, hexagonal as shown in FIG. 14B, and a full-color display device may be realized by arrangement of first films (R) 441, second films (G) 442, and third films (B) 443. In order to form polygonal pixels shown in FIG. 14B, deposition may be performed using an evaporation donor substrate that includes a reflective layer 431 having polygonal openings 432 as shown in FIG. 14A and polygonal light absorption layers.

Application of the present invention makes it easy to form a layer containing an evaporation material for forming a light emitting element and to manufacture a light emitting device including the light emitting element. Application of the present invention also makes it possible to form a flat even film. Application of the present invention facilitates patterning of a light emitting layer; thus, it also facilitates manufacture of a light emitting device. In addition, a precise pattern can be formed; thus, a high-definition light emitting device can be obtained. Furthermore, by application of the present invention, not only a laser but also a lamp heater or the like which is inexpensive but provides a large amount of heat can be used as a light source. Accordingly, manufacturing cost of a light emitting device can be reduced.

In addition, when the present invention is applied, less complicated control is needed in the case where a light emitting layer in which a dopant material is dispersed in a host material is formed, compared with the case where co-evaporation is applied. Moreover, because the additive amount of a dopant material, or the like is easy to control, deposition can be performed easily and precisely, and therefore a desired emission color can be obtained more easily. Furthermore, use efficiency of an evaporation material can be increased; thus, costs can be reduced.

Note that this embodiment mode can be appropriately combined with any of the other embodiment modes in this specification.

### Embodiment Mode 3

In this embodiment mode, a manufacturing method of a light emitting element and a light emitting device by application of the present invention is described.

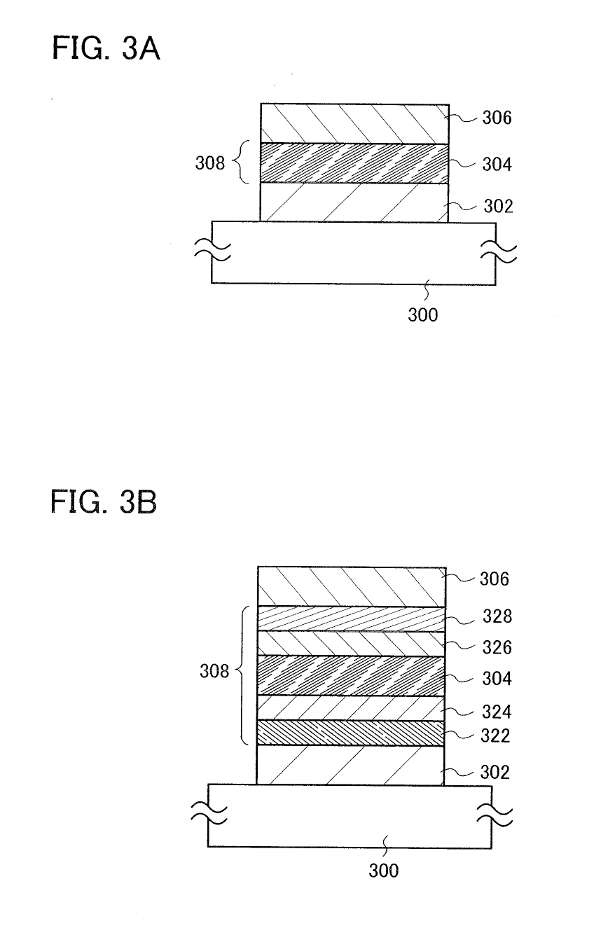

For example, light emitting elements shown in FIGS. 3A and 3B can be manufactured. In the light emitting element shown in FIG. 3A, a first electrode layer 302, an EL layer 308 which functions as a light emitting layer 304, and a second electrode layer 306 are stacked in this order over a substrate 300. One of the first electrode layer 302 and the second electrode layer 306 functions as an anode, and the other functions as a cathode. Holes injected from an anode and electrons injected from a cathode are recombined in the light emitting layer 304, whereby light emission can be obtained. In this embodiment mode, the first electrode layer 302 functions as the anode and the second electrode layer 306 functions as the cathode.

In the light emitting element shown in FIG. 3B, in addition to the components shown in FIG. 3A, a hole injecting layer, a hole transporting layer, an electron transporting layer, and an electron injecting layer are provided. The hole transporting layer is provided between the anode and the light emitting layer. The hole injecting layer is provided between the anode and the light emitting layer or between the anode and the hole transporting layer. On the other hand, the electron transporting layer is provided between the cathode and the light emitting layer. The electron injecting layer is provided between the cathode and the light emitting layer or between the cathode and the electron transporting layer. Note that not all of the hole injecting layer, the hole transporting layer, the electron transporting layer, and the electron injecting layer are necessarily provided, and a layer which is to be provided may be selected as appropriate in accordance with a desired function or the like. In FIG. 3B, the first electrode layer 302 which functions as an anode, a hole injecting layer 322, a hole transporting layer 324, the light emitting layer 304, an electron transporting layer 326, an electron injecting layer 328, and the second electrode layer 306 which functions as a cathode are stacked in this order over the substrate 300.

As the substrate 300, a substrate having an insulating surface or an insulating substrate is employed. Specifically, any of a variety of glass substrates used for the electronics industry, such as an aluminosilicate glass substrate, an aluminoborosilicate glass substrate, or a barium borosilicate glass substrate; a quartz substrate; a ceramic substrate; a sapphire substrate; or the like can be used.

For the first electrode layer 302 and the second electrode layer 306, any of various types of metals, alloys, electrically conductive compounds, mixtures thereof, and the like can be used. Examples include: indium tin oxide (ITO); indium tin oxide containing silicon or silicon oxide; indium zinc oxide (IZO); indium oxide containing tungsten oxide and zinc oxide (IWZO); and the like. Films of these conductive metal oxides are generally formed by sputtering, but they may be formed by application of a sol-gel method or the like. For example, a film of indium zinc oxide (IZO) can be formed by a sputtering method using a target in which zinc oxide of 1 wt % to 20 wt % is added to indium oxide. A film of indium oxide containing tungsten oxide and zinc oxide (IWZO) can be formed by a sputtering method using a target which contains tungsten oxide of 0.5 wt % to 5 wt % and zinc oxide of 0.1 wt % to 1 wt % with respect to indium oxide. Other examples include: gold (Au); platinum (Pt); nickel (Ni); tungsten (W); chromium (Cr); molybdenum (Mo); iron (Fe); cobalt (Co); copper (Cu); palladium (Pd); nitride of a metal material (such as titanium nitride); and the like. Furthermore, aluminum (Al), silver (Ag), an alloy containing aluminum (AlSi), or the like can be used. Moreover, any of the following materials having a low work function can be used: elements which belong to Group 1 and Group 2 of the periodic table, that is, alkali metals such as lithium (Li) and cesium (Cs) and alkaline-earth metals such as magnesium (Mg), calcium (Ca), and strontium (Sr), and alloys thereof (an alloy of aluminum, magnesium, and silver, and an alloy of aluminum and lithium); rare earth metals such as europium (Eu) and ytterbium (Yb), and alloys thereof; and the like. Films of alkali metals, alkaline earth metals, and alloys thereof can be formed by a vacuum evaporation method. Furthermore, films of alloys each containing an alkali metal or an alkaline earth metal can be formed by a sputtering method. The first electrode layer 302 and the second electrode layer 306 can be formed using a silver paste or the like by an inkjet method or the like. Each of the first electrode layer 302 and the second electrode layer 306 is not limited to a single-layer film and can be formed as a stacked-layer film.

Note that, in order to extract light emitted from the light emitting layer 304 to the outside, one or both of the first electrode layer 302 and the second electrode layer 306 is/are formed so as to transmit light. For example, one or both of the first electrode layer 302 and the second electrode layer 306 is/are formed using a conductive material having a light-transmitting property, such as indium tin oxide, or formed using silver, aluminum, or the like to a thickness of several nanometers to several tens of nanometers. Alternatively, one or both of the first electrode layer 302 and the second electrode layer 306 can have a stacked-layer structure including a thin film of a metal such as silver, aluminum, or the like with a small thickness and a thin film of a conductive material having a light-transmitting property, such as ITO. Note that the first electrode layer 302 or the second electrode layer 306 may be formed by any of various methods.

The light emitting layer 304, the hole injecting layer 322, the hole transporting layer 324, the electron transporting layer 326, or the electron injecting layer 328 can be formed by application of the deposition method described above in Embodiment Mode 1. In addition, the electrode layer can also be formed by application of the deposition method described above in Embodiment Mode 1.

For example, in the case where the light emitting element shown in FIG. 3A is formed, a reflective layer is formed on a first surface side of a supporting substrate; a light absorption layer and a first layer containing an evaporation material, which serves as an evaporation source for forming a light emitting layer, are formed on a second surface side of the supporting substrate facing the first surface; and the supporting substrate is disposed close to a deposition target substrate. By light irradiation, the first layer containing the evaporation material which is formed over the supporting substrate is heated and sublimed to form the light emitting layer 304 over the deposition target substrate. Then, the second electrode layer 306 is formed over the light emitting layer 304. The deposition target substrate here is the substrate 300. Note that, over the deposition target substrate, the first electrode layer 302 is formed in advance.

Various kinds of materials can be used for the light emitting layer 304. For example, a fluorescent compound which exhibits fluorescence or a phosphorescent compound which exhibits phosphorescence can be used.

Examples of phosphorescent compounds that can be used for the light emitting layer are given below. Examples of blue light emitting materials include: bis[2-(4′,6′-difluorophenyl)pyridinato-N,C^{2′}]iridium(III) tetrakis(1-pyrazolyl)borate (abbr.: FIr6); bis[2-(4′,6′-difluorophenyl)pyridinato-N,C^{2′}]iridium(III) picolinate (abbr.: FIrpic); bis[2-(3′,5′bistrifluoromethylphenyl)pyridinato-N,C^{2,} ]iridium(III) picolinate (abbr.: Ir(CF₃ppy)₂(pic)); bis[2-(4′,6′-difluorophenyl)pyridinato-N,C^{2′}]iridium(III) acetylacetonate (abbr.: Fir(acac)); and the like. Examples of green light emitting materials include: tris(2-phenylpyridinato-N,C^{2′})iridium(III) (abbr.: Ir(ppy)₃); bis(2-phenylpyridinato-N,C^{2′})iridium(III) acetylacetonate (abbr.: Ir(ppy)₂(acac)); bis(1,2-diphenyl-1H-benzimidazolato)iridium(III) acetylacetonate (abbr.: Ir(pbi)₂(acac)); bis(benzo[h]quinolinato)iridium(III) acetylacetonate (abbr.: Ir(bzq)₂(acac)); and the like. Examples of yellow light emitting material include: bis(2,4-diphenyl-1,3-oxazolato-N,C^{2′})iridium(III) acetylacetonate (abbr.: Ir(dpo)₂(acac)); bis[2-(4′-perfluorophenylphenyl)pyridinato]iridium(III) acetylacetonate (abbr.: Ir(p-PF-ph)₂(acac)); bis(2-phenylbenzothiazolato-N,C^{2′})iridium(III) acetylacetonate (abbr.: Ir(bt)₂(acac)); and the like. Examples of orange light emitting materials include: tris(2-phenylquinolinato-N,C^{2′})iridium(III) (abbr.: Ir(pq)₃); bis(2-phenylquinolinato-N,C_{2′})iridium(III) acetylacetonate (abbr.: Ir(pq)₂(acac)); and the like. Examples of red light emitting materials include organic metal complexes, such as bis[2-(2′-benzo[4,5-α]thienyl)pyridinato-N,C^{3′}]iridium(III) acetylacetonate (abbr.: Ir(btp)₂(acac)), bis(1-phenylisoquinolinato-N,C^{2′})iridium(III) acetylacetonate (abbr.: Ir(piq)₂(acac)), (acetylacetonato)bis [2,3-bis(4-fluorophenyl)quinoxalinato]iridium(III) (abbr.: Ir(Fdpq)₂(acac)), and 2,3,7,8,12,13,17,18-octaethyl-21H,23H-porphyrin platinum(II) (abbr.: PtOEP). In addition, rare-earth metal complexes, such as tris(acetylacetonato)(monophenanthroline)terbium(III) (abbr.: Tb(acac)₃(Phen)), tris(1,3-diphenyl-1,3-propanedionato)(monophenanthroline)europium(III) (abbr.: Eu(DBM)₃(Phen)), and tris[1-(2-thenoyl)-3,3,3-trifluoroacetonato](monophenanthroline)europium(III) (abbr.: Eu(TTA)₃(Phen)), exhibit light emission from rare-earth metal ions (electron transition between different multiplicities); thus, rare-earth metal complexes can be used as phosphorescent compounds.

Examples of fluorescent compounds that can be used for the light emitting layer are given below. Examples of blue light emitting materials include: N,N′-bis[4-(9H-carbazol-9-yl)phenyl]-N,N′-diphenylstilbene-4,4′-diamine (abbr.: YGA2S); 4-(9H-carbazol-9-yl)-4′-(10-phenyl-9-anthryl)triphenylamine (abbr.: YGAPA); and the like. Examples of green light emitting materials include: N-(9,10-diphenyl-2-anthryl)-N,9-diphenyl-9H-carbazol-3-amine (abbr.: 2PCAPA); N-[9,10-bis(1,1′-biphenyl-2-yl)-2-anthryl]-N,9-diphenyl-9H-carbazol-3-amine (abbr.: 2PCABPhA); N-(9,10-diphenyl-2-anthryl)-N,N′,N′-triphenyl-1,4-phenylenediamine (abbr.: 2DPAPA); N-[9,10-bis(1,1′-biphenyl-2-yl)-2-anthryl]-N,N′,N′-triphenyl-1,4-phenylenediamine (abbr.: 2DPABPhA); 9,10-bis(1,1′-biphenyl-2-yl)-N-[4-(9H-carbazol-9-yl)phenyl]-N-phenylanthracen-2-amine (abbr.: 2YGABPhA); N,N,9-triphenylanthracen-9-amine (abbr.: DPhAPhA); and the like. Examples of yellow light emitting materials include: rubrene; 5,12-bis(1,1′-biphenyl-4-yl)-6,11-diphenyltetracene (abbr.: BPT); and the like. Examples of red light emitting materials include: N,N,N′,N′-tetrakis(4-methylphenyl)tetracene-5,11-diamine (abbr.: p-mPhTD); 7,13-diphenyl-N,N,N′,N′-tetrakis(4-methylphenyl)acenaphtho[1,2-a]fluoranthene-3,10-d iamine (abbr.: p-mPhAFD); and the like.

The light emitting layer 304 may have a structure in which a substance having a high light emitting property (a dopant material) is dispersed in another substance (a host material), whereby crystallization of the light emitting layer can be suppressed. In addition, concentration quenching which results from high concentration of the substance having a high light emitting property can be suppressed.

As the substance in which the substance having a high light emitting property is dispersed, when the substance having a high light emitting property is a fluorescent compound, a substance having singlet excitation energy (the energy difference between a ground state and a singlet excited state) higher than the fluorescent compound is preferably used. When the substance having a high light emitting property is a phosphorescent compound, a substance having higher triplet excitation energy (the energy difference between a ground state and a triplet excited state) than the phosphorescent compound is preferably used.

Examples of host materials used for the light emitting layer include: 4,4′-bis[N-(1-naphthyl)-N-phenylamino]biphenyl (abbr.: NPB); tris(8-quinolinolato)aluminum(III) (abbr.: Alq); 4,4′-bis[N-(9,9-dimethylfluorene-2-yl)-N-phenylamino]biphenyl (abbr.: DFLDPBi); bis(2-methyl-8-quinolinolato)(4-phenylphenolato)aluminum(III) (abbr.: BAlq); 4,4′-di(9-carbazolyl)biphenyl (abbr.: CBP); 2-tert-butyl-9,10-di(2-naphthyl)anthracene (abbr: t-BuDNA); 9-[4-(9-carbazolyl)phenyl]-10-phenylanthracene (abbr.: CzPA); and the like.

As the dopant material, any of the above-mentioned phosphorescent compounds and fluorescent compounds can be used.

When the light emitting layer has a structure in which a substance having a high light emitting property (a dopant material) is dispersed in another substance (a host material), a mixed layer of a host material and a guest material is formed as the first layer containing the evaporation material which serves as an evaporation source. Alternatively, the first layer containing the evaporation material which serves as an evaporation source may have a structure in which a layer containing a host material and a layer containing a dopant material are stacked. The light emitting layer 304, when formed using an evaporation source having such a structure, contains a substance in which a light emitting material is dispersed (host material) and a substance having a high light emitting property (dopant material), and has a structure in which the substance having a high light emitting property (dopant material) is dispersed in the substance in which a light emitting material is dispersed (host material). Note that, for the light emitting layer, two or more kinds of host materials and a dopant material may be used, or two or more kinds of dopant materials and a host material may be used. Alternatively, two or more kinds of host materials and two or more kinds of dopant materials may be used.

In addition, in the case where the light emitting element shown in FIG. 3B, in which various functional layers are stacked, is formed, the following procedure may be repeated: a layer containing an evaporation material is formed over a supporting substrate; the supporting substrate is disposed close to a deposition target substrate; the layer containing the evaporation material which is formed over the supporting substrate is heated and sublimed, thereby forming a functional layer over the deposition target substrate. For example, a first layer containing an evaporation material which serves as an evaporation source for forming a hole injecting layer is formed over a supporting substrate by using a material for forming the hole injecting layer as the first evaporation material; the supporting substrate is disposed close to a deposition target substrate; and the first layer containing the evaporation material which is formed over the supporting substrate is heated and sublimed, thereby forming the hole injecting layer 322 over the deposition target substrate. The deposition target substrate here is the substrate 300 and is provided with the first electrode layer 302 in advance. Successively, a first layer containing an evaporation material which serves as an evaporation source for forming a hole transporting layer is formed over a supporting substrate by using a material for forming the hole transporting layer as the first evaporation material; the supporting substrate is disposed close to the deposition target substrate; and the first layer containing the evaporation material which is formed over the supporting substrate is heated and sublimed, thereby forming the hole transporting layer 324 over the hole injecting layer 322 over the deposition target substrate. After that, the light emitting layer 304, the electron transporting layer 326, and the electron injecting layer 328 are sequentially stacked in a similar manner, and then the second electrode layer 306 is formed.

The hole injecting layer 322, the hole transporting layer 324, the electron transporting layer 326, or the electron injecting layer 328 may be formed using various EL materials. Each layer may be formed using one kind of material or a composite material of plural kinds of materials. In the case where a layer is formed using a composite material, a first layer containing plural kinds of evaporation materials is formed as described above. Alternatively, a first layer containing an evaporation material is formed by stacking a plurality of layers each containing an evaporation material. In the case where a layer is formed using one kind of material, the deposition method described above in Embodiment Mode 1 can also be applied. Moreover, each of the hole injecting layer 322, the hole transporting layer 324, the electron transporting layer 326, and the electron injecting layer 328 may have a single-layer structure or a stacked-layer structure. For example, the hole transporting layer 324 may have a stacked-layer structure of a first hole transporting layer and a second hole transporting layer. In addition, the electrode layer can be formed by the deposition method described in Embodiment Mode 1.

For example, the hole injecting layer 322 can be formed using molybdenum oxide, vanadium oxide, ruthenium oxide, tungsten oxide, manganese oxide, or the like. Alternatively, the hole injecting layer can be formed using a phthalocyanine-based compound such as phthalocyanine (abbr.: H₂Pc) or copper phthalocyanine (abbr.: CuPc), a high molecular compound such as poly(3,4-ethylenedioxythiophene)/poly(styrenesufonate) (PEDOT/PSS), or the like.

As the hole injecting layer 322, a layer which contains a substance having a high hole transporting property and a substance having an electron accepting property can be used. The layer which contains a substance having a high hole transporting property and a substance having an electron accepting property has high carrier density and an excellent hole injecting property. When the layer which contains a substance having a high hole transporting property and a substance having an electron accepting property is used as a hole injecting layer which is in contact with an electrode that functions as an anode, any of various kinds of metals, alloys, electrically conductive compounds, mixtures thereof, and the like can be used for the electrode layer regardless of the magnitude of work function of a material of the electrode layer which functions as an anode.

The layer which contains a substance having a high hole transporting property and a substance having an electron accepting property can be formed using, for example, a stack of a layer which contains a substance having a high hole transporting property and a layer which contains a substance having an electron accepting property as an evaporation source.

Examples of the substance having an electron accepting property, which is used for the hole injecting layer, include: 7,7,8,8-tetracyano-2,3,5,6-tetrafluoroquinodimethane (abbr.: F₄-TCNQ); chloranil; and the like. Other examples are transition metal oxides. Still other examples are oxides of metals belonging to Groups 4 to 8 of the periodic table. Specifically, vanadium oxide, niobium oxide, tantalum oxide, chromium oxide, molybdenum oxide, tungsten oxide, manganese oxide, and rhenium oxide are preferable because of their high electron-accepting properties. Among them, molybdenum oxide is especially preferable because it is stable also in the atmosphere, has a lows hygroscopic property, and can be easily handled.

As the substance having a high hole transporting property used for the hole injecting layer, any of various compounds such as aromatic amine compounds, carbazole derivatives, aromatic hydrocarbons, and high molecular compounds (such as oligomers, dendrimers, and polymers) can be used. Note that it is preferable that the substance having a high hole transporting property used for the hole injecting layer be a substance having a hole mobility of 10⁻⁶ cm²/Vs or higher. Note that any other substance that has a hole transporting property which is higher than an electron transporting property may be used. Specific examples of the substance having a high hole transporting property, which can be used for the hole injecting layer, are given below.

Examples of aromatic amine compounds that can be used for the hole injecting layer include: 4,4′-bis[N-(1-naphthyl)-N-phenylamino]biphenyl (abbr.: NPB); N,N′-bis(3-methylphenyl)-N,N′-diphenyl-[1,1′-biphenyl]-4,4′-diamine (abbr.: TPD); 4,4′,4″-tris(N,N-diphenylamino)triphenylamine (abbr.: TDATA); 4,4′,4″-tris[N-(3-methylphenyl)-N-phenylamino]triphenylamine (abbr.: MTDATA); 4,4′-bis[N-(spiro-9,9′-bifluoren-2-yl)-N-phenylamino]biphenyl (abbr.: BSPB); and the like. Other examples are as follows: N,N-bis(4-methylphenyl)(p-tolyl)-N,N′-diphenyl-p-phenylenediamine (abbr.: DTDPPA); 4,4′-bis[N-(4-diphenylaminophenyl)-N-phenylamino]biphenyl (abbr.: DPAB); 4,4′-bis(N-{4-[N′-(3-methylphenyl)-N′-phenylamino]phenyl}-N-phenylamino)biphenyl (abbr.: DNTPD); 1,3,5-tris[N-(4-diphenylaminophenyl)-N-phenylamino]benzene (abbr.: DPA3B); and the like.

Specific examples of carbazole derivatives that can be used for the hole injecting layer include: 3-[N-(9-phenylcarbazol-3-yl)-N-phenylamino]-9-phenylcarbazole (abbr.: PCzPCA1); 3,6-bis[N-(9-phenylcarbazol-3-yl)-N-phenylamino]-9-phenylcarbazole (abbr.: PCzPCA2); 3-[N-(1-naphthyl)-N-(9-phenylcarbazol-3-yl)amino]-9-phenylcarbazole (abbr.: PCzPCN1); and the like.

Other examples of carbazole derivatives that can be used for the hole injecting layer include: 4,4′-di(N-carbazolyl)biphenyl (abbr.: CBP); 1,3,5-tris[4-(N-carbazolyl)phenyl]benzene (abbr.: TCPB); 9-[4-(10-phenyl-9-anthryl)phenyl]-9H-carbazole (abbr.: CzPA); 1,4-bis[4-(N-carbazolyl)phenyl]-2,3,5,6-tetraphenylbenzene; and the like.

Examples of aromatic hydrocarbons that can be used for the hole injecting layer include: 2-tert-butyl-9,10-di(2-naphthyl)anthracene (abbr.: t-BuDNA); 2-tert-butyl-9,10-di(1-naphthyl)anthracene; 9,10-bis(3,5-diphenylphenyl)anthracene (abbr.: DPPA); 2-tert-butyl-9,10-bis(4-phenylphenyl)anthracene (abbr.: t-BuDBA); 9,10-di(2-naphthyl)anthracene (abbr.: DNA); 9,10-diphenylanthracene (abbr.: DPAnth); 2-tert-butylanthracene (abbr.: t-BuAnth); 9,10-bis(4-methyl-1-naphthyl)anthracene (abbr.: DMNA); 9,10-bis[2-(1-naphthyl)phenyl]-2-tert-butyl-anthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; 2,5,8,11-tetra(tert-butyl)perylene; and the like. Besides, pentacene, coronene, or the like can also be used. As these aromatic hydrocarbons listed here, it is preferable that an aromatic hydrocarbon having a hole mobility of 1×10⁻⁶ cm²/Vs or more and having 14 to 42 carbon atoms be used.

Note that an aromatic hydrocarbon that can be used for the hole injecting layer may have a vinyl skeleton. Examples of aromatic hydrocarbons having a vinyl group include: 4,4′-bis(2,2-diphenylvinyl)biphenyl (abbr.: DPVBi); 9,10-bis[4-(2,2-diphenylvinyl)phenyl]anthracene (abbl: DPVPA); and the like.

The hole injecting layer can be formed by using an evaporation source in which the layer which contains a substance having a high hole transporting property and the layer which contains a substance having an electron accepting property are stacked. When a metal oxide is used as the substance having an electron accepting property, it is preferable that a layer which contains a metal oxide be formed after the layer which contains a substance having a high hole transporting property be formed over a first substrate. This is because, in many cases, a metal oxide has a higher evaporation temperature than a substance having a high hole transporting property. The evaporation source with such a structure makes it possible to efficiently sublime a substance having a high hole transporting property and a metal oxide. In addition, local non-uniformity of the concentration in a film formed by evaporation can be suppressed. Moreover, there are few kinds of solvents which allow both a substance having a high hole transporting property and a metal oxide to be dissolved or dispersed therein, and a mixed solution is not easily formed. Therefore, it is difficult to directly form a mixed layer by a wet method. However, the use of the deposition method of the present invention makes it possible to easily form a mixed layer which contains a substance having a high hole transporting property and a metal oxide.

In addition, the layer which contains a substance having a high hole transporting property and a substance having an electron accepting property is excellent in not only a hole injecting property but also a hole transporting property, and thus the above-described hole injecting layer may be used as the hole transporting layer.

The hole transporting layer 324 is a layer which contains a substance having a high hole transporting property. Examples of the substance having a high hole transporting property include aromatic amine compounds such as 4,4′-bis[N-(1-naphthyl)-N-phenylamino]biphenyl (abbr.: NPB or α-NPD), N,N′-bis(3-methylphenyl)-N,N′-diphenyl-[1,1′-biphenyl]-4,4′-diamine (abbr.: TPD), 4,4′,4″-tris(N,N-diphenylamino)triphenylamine (abbr.: TDATA), 4,4′,4″-tris[N-(3-methylphenyl)-N-phenylamino]triphenylamine (abbL: MTDATA), and 4,4′-bis[N-(spiro-9,9′-bifluoren-2-yl)-N-phenylamino]biphenyl (abbr.: BSPB), and the like. The substances listed here mainly have a hole mobility of 1×10⁻⁶ cm²/Vs or more. Note that any other material that has a hole transporting property which is higher than an electron transporting property may be used. The layer which contains a substance having a high hole transporting property is not limited to a single layer and may be a stacked layer of two or more layers formed of the above-mentioned substances.

The electron transporting layer 326 is a layer which contains a substance having a high electron transporting property. Examples of the substance having a high electron transporting property include metal complexes having a quinoline skeleton or a benzoquinoline skeleton, such as tris(8-quinolinolato)aluminum (abbr.: Alq), tris(4-methyl-8-quinolinolato)aluminum (abbr.: Almq₃), bis(10-hydroxybenzo[h]quinolinato)beryllium (abbr.: BeBq₂), and bis(2-methyl-8-quinolinolato)(4-phenylphenolato)aluminum (abbr.: BAlq), and the like. Other examples are metal complexes having an oxazole-based ligand or a thiazole-based ligand, such as bis[2-(2-hydroxyphenyl)benzoxazolato]zinc (abbr.: Zn(BOX)₂) and bis[2-(2-hydroxyphenyl)benzothiazolato]zinc (abbr.: Zn(BTZ)₂), and the like. Besides metal complexes, other examples are as follows: 2-(4-biphenylyl)-5-(4-tert-butylphenyl)-1,3,4-oxadiazole (abbr.: PBD); 1,3-bis[5-(p-tert-butylphenyl)-1,3,4-oxadiazol-2-yl]benzene (abbr.: OXD-7); 3-(4-biphenylyl)-4-phenyl-5-(4-tert-biphenyl)-1,2,4-triazole (abbr.: TAZ01); bathophenanthroline (abbr.: BPhen); bathocuproine (abbr.: BCP); and the like. The substances listed here mainly have an electron mobility of 1×10⁻⁶ cm²/Vs or higher. Note that any other material that has an electron transporting property which is higher than a hole transporting property may be used for the electron transporting layer. The electron transporting layer is not limited to a single layer and may be a stacked layer of two or more layers formed of the above-mentioned substances.

The electron injecting layer 328 can be formed using an alkali metal compound or an alkaline earth metal compound, such as lithium fluoride (LiF), cesium fluoride (CsF), or calcium fluoride (CaF₂). Furthermore, a layer, in which a substance having an electron transporting property is combined with an alkali metal or an alkaline earth metal, can be employed. For example, a layer of Alq containing magnesium (Mg) can be used. Note that it is preferable that the layer, in which a substance having an electron transporting property is combined with an alkali metal or an alkaline earth metal, be used as the electron injecting layer because electrons are efficiently injected from the second electrode layer 306.

Note that there is no particular limitation on a stack structure of layers of the EL layer 308. The EL layer 308 may be formed by an appropriate combination of a light emitting layer with any of layers which contain a substance having a high electron transporting property, a substance having a high hole transporting property, a substance having a high electron injecting property, a substance having a high hole injecting property, a bipolar substance (a substance having high electron and hole transporting properties), and the like.

Light emission is extracted to the outside through one or both of the first electrode layer 302 and the second electrode layer 306. Therefore, one or both of the first electrode layer 302 and the second electrode layer 306 is/are an electrode having a light transmitting property. In the case where only the first electrode layer 302 is an electrode having a light transmitting property, light is extracted from the substrate 300 side through the first electrode layer 302. In the case where only the second electrode layer 306 is an electrode having a light transmitting property, light is extracted from the side opposite to the substrate 300 side through the second electrode layer 306. In the case where both the first electrode layer 302 and the second electrode layer 306 are electrodes having light transmitting properties, light is extracted from both the substrate 300 side and the side opposite to the substrate 300 side through the first electrode layer 302 and the second electrode layer 306.

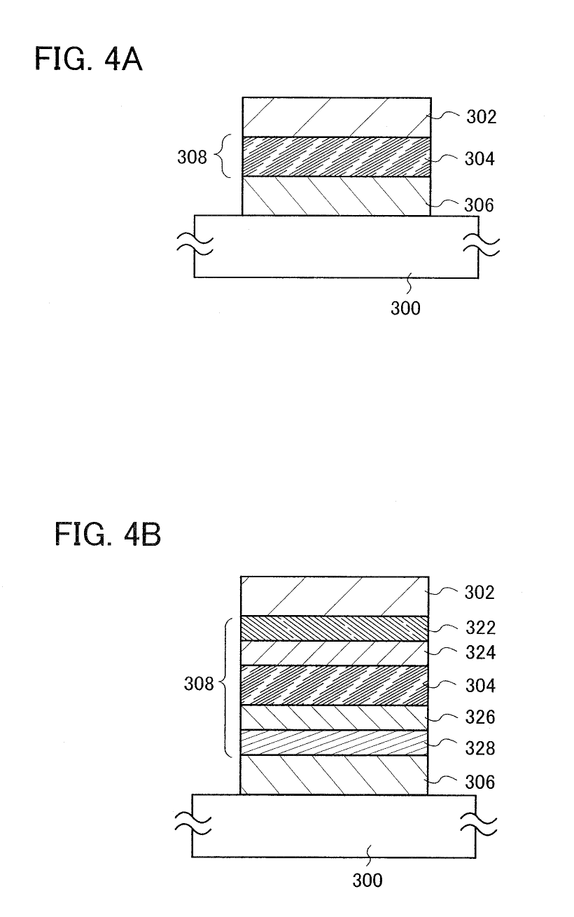

Note that, although FIGS. 3A and 3B each show the structure in which the first electrode layer 302 functioning as an anode is provided on the substrate 300 side, the second electrode layer 306 functioning as a cathode may be provided on the substrate 300 side. FIGS. 4A and 4B each show a structure in which the second electrode layer 306 functioning as a cathode, the EL layer 308, and the first electrode layer 302 functioning as an anode are stacked in order over the substrate 300. In the EL layer 308 shown in FIG. 4B, layers are stacked in the order opposite to that of the EL layer 308 shown in FIG. 3B.

The EL layer is formed by the deposition method described in Embodiment Mode 1 or may be formed by a combination of the deposition method described in Embodiment Mode 1 with another deposition method. The electrodes and the layers may each be formed using a different method. Examples of a dry method include a vacuum evaporation method, an electron beam evaporation method, a sputtering method, and the like. Examples of a wet method include an inkjet method, a spin coating method, and the like.

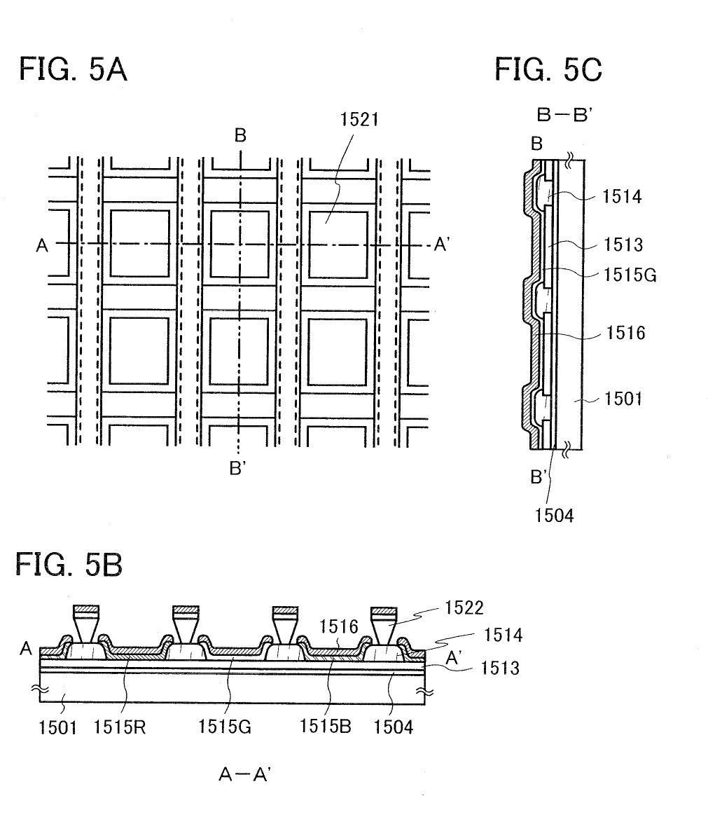

Through the above-described steps, the light emitting element can be manufactured. As for the light emitting element of this embodiment mode, application of the present invention makes it easy to form functional layers including the light emitting layer. Then, a light emitting device can be manufactured by application of such a light emitting element. An example of a passive-matrix light emitting device manufactured by application of the present invention is described with reference to FIGS. 5A to 5C, FIG. 6, and FIG. 7.

In a passive-matrix (also called simple-matrix) light emitting device, a plurality of anodes arranged in stripes (in strip form) are provided to be perpendicular to a plurality of cathodes arranged in stripes. A light emitting layer is interposed at each intersection. Therefore, a pixel at an intersection of an anode selected (to which a voltage is applied) and a cathode selected emits light.

FIG. 5A shows a top view of a pixel portion before sealing. FIG. 5B shows a cross-sectional view taken along a dashed line A-A′ in FIG. 5A. FIG. 5C shows a cross-sectional view taken along a dashed line B-B′.

Over a substrate 1501, an insulating layer 1504 is formed as a base insulating layer. Note that the insulating layer 1504 does not necessarily need to be formed if a base insulating layer is not necessary. A plurality of first electrode layers 1513 are arranged in stripes at regular intervals over the insulating layer 1504. A partition 1514 having openings each corresponding to a pixel is provided over the first electrode layers 1513. The partition 1514 having openings is formed using an insulating material (a photosensitive or nonphotosensitive organic material (polyimide, acrylic, polyamide, polyimide amide, or benzocyclobutene) or an SOG film (such as a SiOₓ film including an alkyl group)). Note that each opening corresponding to a pixel is a light emitting region 1521.

Over the partition 1514 having openings, a plurality of inversely tapered partitions 1522 parallel to each other are provided to intersect with the first electrode layers 1513. The inversely tapered partitions 1522 are formed by a photolithography method using a positive-type photosensitive resin, of which portion unexposed to light remains as a pattern, and by adjusting the amount of light exposure or the length of development time so that a lower portion of a pattern is etched more.

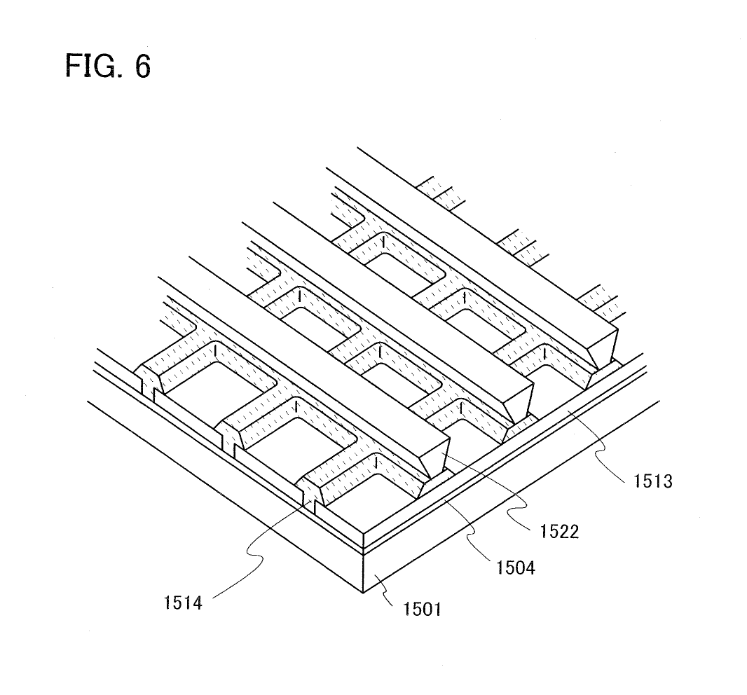

FIG. 6 shows a perspective view immediately after formation of the plurality of inversely tapered partitions 1522 parallel to each other. Note that the same reference numerals are used to denote the same portions as those in FIGS. 5A to 5C.

The total thickness of the partition 1514 having openings and each of the inversely tapered partitions 1522 is set to be larger than the total thickness of an EL layer including a light emitting layer and a conductive layer serving as a second electrode layer. When an EL layer including a light emitting layer and a conductive layer are stacked over the substrate having the structure shown in FIG. 6, they are separated into a plurality of regions, so that EL layers 1515R, 1515G, and 1515B each including a light emitting layer, and second electrode layers 1516 are formed as shown in FIGS. 5A to 5C. Note that the plurality of separated regions are electrically isolated from each other. The second electrode layers 1516 are electrodes in stripes which are parallel to each other and extended along a direction intersecting with the first electrode layers 1513. Note that EL layers each including a light emitting layer and conductive layers are also formed over the inversely tapered partitions 1522; however, they are separated from the EL layers 1515R, 1515G, and 1515B each including a light emitting layer and the second electrode layers 1516. Note that the ELlayer in this embodiment mode is a layer including at least a light emitting layer and may include a hole injecting layer, a hole transporting layer, an electron transporting layer, an electron injecting layer, or the like in addition to the light emitting layer.

In this embodiment mode, an example is described in which the EL layers 1515R, 1515G, and 1515B each including a light emitting layer are selectively formed to form a light emitting device which provides three kinds of light emission (R,G,B) and is capable of performing full color display. The EL layers 1515R, 1515G, and 1515B each including a light emitting layer are formed in a pattern of stripes parallel to each other. These EL layers may be formed by the deposition method described in Embodiment Modes 1 and 2. For example, a first supporting substrate provided with an evaporation source for a light emitting layer providing red light emission, a second supporting substrate provided with an evaporation source for a light emitting layer providing green light emission, and a third supporting substrate provided with an evaporation source for a light emitting layer providing blue light emission are separately prepared. In addition, a substrate provided with the first electrode layers 1513 is prepared as a deposition target substrate. Then, one of the first to third supporting substrates is appropriately disposed to face the deposition target substrate, and the evaporation source formed over the supporting substrate is heated and sublimed, thereby forming EL layers including a light emitting layer over the deposition target substrate. Note that a mask or the like is appropriately used to selectively form EL layers in a desired position.

Furthermore, if necessary, sealing is performed using a sealant such as a sealant can or a glass substrate for sealing. In this embodiment mode, a glass substrate is used as a sealing substrate, and a substrate and the sealing substrate are attached to each other with an adhesive material such as a sealing material to seal a space surrounded by the adhesive material such as a sealing material. The space that is sealed is filled with a filler or a dry inert gas. In addition, a desiccant or the like may be put between the substrate and the sealing material so that reliability of the light emitting device is increased. A small amount of moisture is removed by the desiccant, whereby sufficient drying is performed. The desiccant may be a substance which absorbs moisture by chemical adsorption such as an oxide of an alkaline earth metal as typified by calcium oxide or barium oxide. A substance which adsorbs moisture by physical adsorption such as zeolite or silica gel may alternatively be used.

Note that, if the sealant is provided covering and in contact with the light emitting element to sufficiently block the outside air, the desiccant is not necessarily provided.

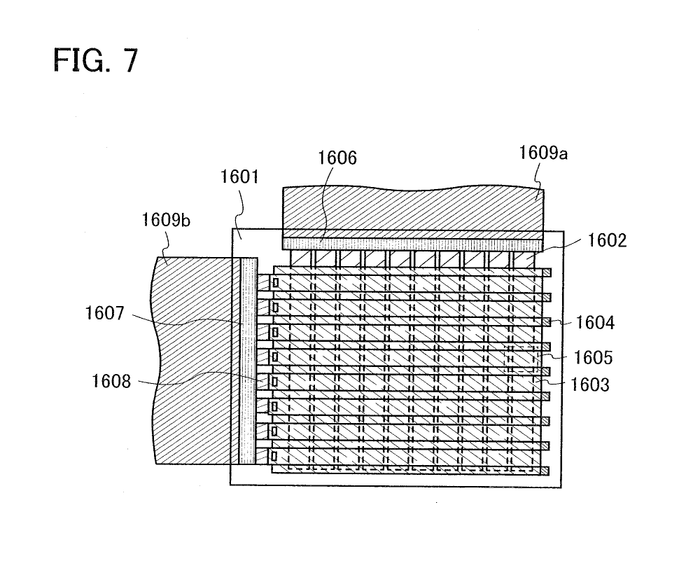

FIG. 7 shows a top view of a light emitting module mounted with an FPC or the like.

Note that the light emitting device in this specification refers to an image display device, a light emitting device, or a light source (including a lighting device). Furthermore, the light emitting device includes any of the following modules in its category: a module in which a connector such as a flexible printed circuit (FPC), a tape automated bonding (TAB) tape, or a tape carrier package (TCP) is attached to a light emitting device; a module having a TAB tape or a TCP provided with a printed wiring board at the end thereof; and a module having an integrated circuit (IC) directly mounted by a chip-on-glass (COG) method on a substrate provided with a light emitting element.

In a pixel portion for displaying images, scan lines and data lines intersect with each other perpendicularly as shown in FIG. 7.

The first electrode layers 1513 in FIGS. 5A to 5C correspond to scan lines 1603 in FIG. 7; the second electrode layers 1516 correspond to data lines 1602; the inversely tapered partitions 1522 correspond to partitions 1604; and the substrate 1501 corresponds to the substrate 1601. EL layers each including a light emitting layer are sandwiched between the data lines 1602 and the scan lines 1603, and an intersection portion indicated by a region 1605 corresponds to one pixel.

Note that the scan lines 1603 are electrically connected at their ends to connection wirings 1608, and the connection wirings 1608 are connected to an FPC 1609b through an input terminal 1607. The data lines 1602 are connected to an FPC 1609a through an input terminal 1606.

If necessary, a polarizing plate, a circularly polarizing plate (including an elliptically polarizing plate), a retardation plate (a quarter-wave plate or a half-wave plate), or an optical film such as a color filter may be appropriately provided over a light emitting surface. Further, the polarizing plate or the circularly polarizing plate may be provided with an anti-reflection film. For example, anti-glare treatment may be carried out by which reflected light can be diffused by projections and depressions on the surface so as to reduce the glare.

In the above-described manner, a passive-matrix light emitting device can be manufactured. Application of the present invention makes it easy to form a layer containing an evaporation material forming a light emitting element and to manufacture a light emitting device including the light emitting element. In addition, less complicated control is needed in the case where a light emitting layer in which a dopant material is dispersed in a host material is formed than in the case where co-evaporation is applied. Moreover, because the additive amount of a dopant material, or the like can be easily controlled, deposition can be performed easily and precisely, and therefore a desired emission color can also be obtained easily. Furthermore, use efficiency of an evaporation material can be increased; thus, cost can be reduced.

Application of the present invention also makes it possible to form a flat even film. Application of the present invention facilitates patterning of a light emitting layer; thus, it also facilitates manufacture of a light emitting device. In addition, a precise pattern can be formed; thus, a high-definition light emitting device can be obtained. Furthermore, by application of the present invention, not only a laser but also a lamp heater or the like which is inexpensive but provides a large amount of heat can be used as a light source. Accordingly, manufacturing cost of a light emitting device can be reduced.

Although FIG. 7 shows the example in which a driver circuit is not provided over the substrate, the present invention is not particularly limited to this example and an IC chip including a driver circuit may be mounted on the substrate.

In the case where an IC chip is mounted, a data line side IC and a scan line side IC, in each of which a driver circuit for transmitting a signal to the pixel portion is formed, are mounted on the periphery of (outside of) the pixel portion by a COG method. The mounting may be performed using TCP or a wire bonding method other than the COG method. TCP is a TAB tape mounted with an IC, and the TAB tape is connected to a wiring over an element-forming substrate, thereby mounting the IC. Each of the data line side IC and the scan line side IC may be formed using a silicon substrate. Alternatively, it may be that in which a driver circuit is formed using TFTs over a glass substrate, a quartz substrate, or a plastic substrate. Although described here is an example in which a single IC is provided on one side, a plurality of ICs may be provided on one side.

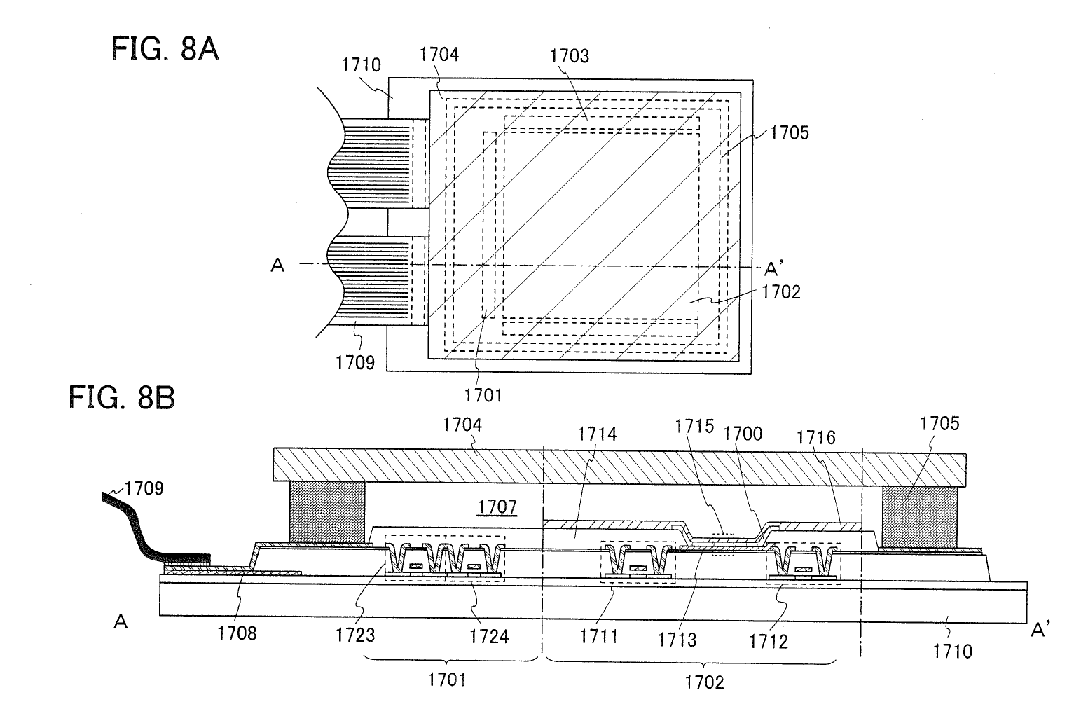

Next, an example of an active-matrix light emitting device which is manufactured by application of the present invention is described with reference to FIGS. 8A and 8B. Note that FIG. 8A is a top view showing a light emitting device and FIG. 8B is a cross-sectional view taken along a chain line A-A′ in FIG. 8A. The active-matrix light emitting device of this embodiment mode includes a pixel portion 1702 provided over an element substrate 1710, a driver circuit portion (a source-side driver circuit) 1701, and a driver circuit portion (a gate-side driver circuit) 1703. The pixel portion 1702, the driver circuit portion 1701, and the driver circuit portion 1703 are sealed, with a sealant 1705, between the element substrate 1710 and a sealing substrate 1704.

In addition, over the element substrate 1710, a lead wiring 1708 for connecting an external input terminal, through which a signal (e.g., a video signal, a clock signal, a start signal, a reset signal, or the like) or an electric potential is transmitted to the driver circuit portion 1701 and the driver circuit portion 1703, is provided. In this embodiment mode, an example is described in which a flexible printed circuit (FPC) 1709 is provided as the external input terminal. Note that only the FPC is shown here; however, the FPC may be provided with a printed wiring board (PWB). The light emitting device in this specification includes not only the main body of the light emitting device, but also the light emitting device with an FPC or a PWB attached thereto.

Next, a cross-sectional structure is described with reference to FIG. 8B. The driver circuit portions and the pixel portion are formed over the element substrate 1710; however, the pixel portion 1702 and the driver circuit portion 1701 which is the source-side driver circuit are shown in FIG. 8B.

An example is shown in which a CMOS circuit which is a combination of an n-channel TFT 1723 and a p-channel TFT 1724 is formed as the driver circuit portion 1701. Note that a circuit included in the driver circuit portion may be formed using various CMOS circuits, PMOS circuits, or NMOS circuits. In this embodiment mode, a driver-integrated type in which a driver circuit is formed over a substrate is shown; however, it is not necessarily required to have the structure, and a driver circuit can be formed not on but outside the substrate.

The pixel portion 1702 includes a plurality of pixels, each of which includes a switching TFT 1711, a current-controlling TFT 1712, and a first electrode layer 1713 which is electrically connected to a wiring (a source electrode or a drain electrode) of the current-controlling TFT 1712. Note that an insulator 1714 is formed covering an end portion of the first electrode layer 1713. In this embodiment mode, the insulator 1714 is formed using a positive photosensitive acrylic resin.

The insulator 1714 is preferably formed so as to have a curved surface with curvature at an upper end portion or a lower end portion thereof in order to obtain favorable coverage by a film which is to be stacked over the insulator 1714. For example, in the case of using a positive photosensitive acrylic resin as a material for the insulator 1714, the insulator 1714 is preferably formed so as to have a curved surface with a curvature radius (0.2 μm to 3 μm) at the upper end portion thereof. Either a negative photosensitive material which becomes insoluble in an etchant by light irradiation or a positive photosensitive material which becomes soluble in an etchant by light irradiation can be used for the insulator 1714. As the insulator 1714, without limitation to an organic compound, either an organic compound or an inorganic compound such as silicon oxide or silicon oxynitride can be used.

An EL layer 1700 including a light emitting layer and a second electrode layer 1716 are stacked over the first electrode layer 1713. The first electrode layer 1713 corresponds to the above-described first electrode layer 302, and the second electrode layer 1716 corresponds to the above-described second electrode layer 306. Note that when an ITO film is used as the first electrode layer 1713, and a stacked film of a titanium nitride film and a film containing aluminum as its main component or a stacked film of a titanium nitride film, a film containing aluminum as its main component, and a titanium nitride film is used as the wiring of the current-controlling TFT 1712 which is connected to the first electrode layer 1713, resistance of the wiring is low and favorable ohmic contact with the ITO film can be obtained. Note that, although not shown in FIGS. 8A and 8B, the second electrode layer 1716 is electrically connected to the FPC 1709 which is an external input terminal.

In the EL layer 1700, at least the light emitting layer is provided, and in addition to the light emitting layer, a hole injecting layer, a hole transporting layer, an electron transporting layer, or an electron injecting layer is provided as appropriate. The first electrode layer 1713, the EL layer 1700, and the second electrode layer 1716 are stacked, whereby a light emitting element 1715 is formed.

Although the cross-sectional view of FIG. 8B shows only one light emitting element 1715, a plurality of light emitting elements are arranged in matrix in the pixel portion 1702. Light emitting elements which provide three kinds of light emissions (R, G, and B) are selectively formed in the pixel portion 1702, whereby a light emitting device capable of full color display can be formed. Alternatively, by a combination with color filters, a light emitting device capable of full color display may be formed.

Furthermore, the sealing substrate 1704 and the element substrate 1710 are attached to each other with the sealant 1705, whereby the light emitting element 1715 is provided in a space 1707 surrounded by the element substrate 1710, the sealing substrate 1704, and the sealant 1705. Note that the space 1707 may be filled with the sealant 1705 or with an inert gas (such as nitrogen or argon).

Note that an epoxy-based resin is preferably used as the sealant 1705. It is preferable that such a material transmit as little moisture and oxygen as possible. As the sealing substrate 1704, a plastic substrate formed of fiberglass-reinforced plastics (FRP), polyvinyl fluoride (PVF), polyester, acrylic, or the like can be used besides a glass substrate or a quartz substrate.

As described above, the light emitting device can be obtained by application of the present invention. An active-matrix light emitting device tends to require high manufacturing cost per device because TFTs are manufactured; however, application of the present invention makes it possible to drastically reduce loss of materials in forming light emitting elements. Thus, cost can be reduced.

Application of the present invention makes it easy to form a layer containing an evaporation material for forming a light emitting element and to manufacture a light emitting device including the light emitting element. Application of the present invention also makes it possible to form a flat even film. Application of the present invention facilitates patterning of a light emitting layer; thus, it also facilitates manufacture of a light emitting device. In addition, a precise pattern can be formed; thus, a high-definition light emitting device can be obtained. Furthermore, by application of the present invention, not only a laser but also a lamp heater or the like which is inexpensive but provides a large amount of heat can be used as a light source. Accordingly, manufacturing cost of a light emitting device can be reduced.

Note that this embodiment mode can be appropriately combined with any of the other embodiment modes described in this specification.

### Embodiment Mode 4

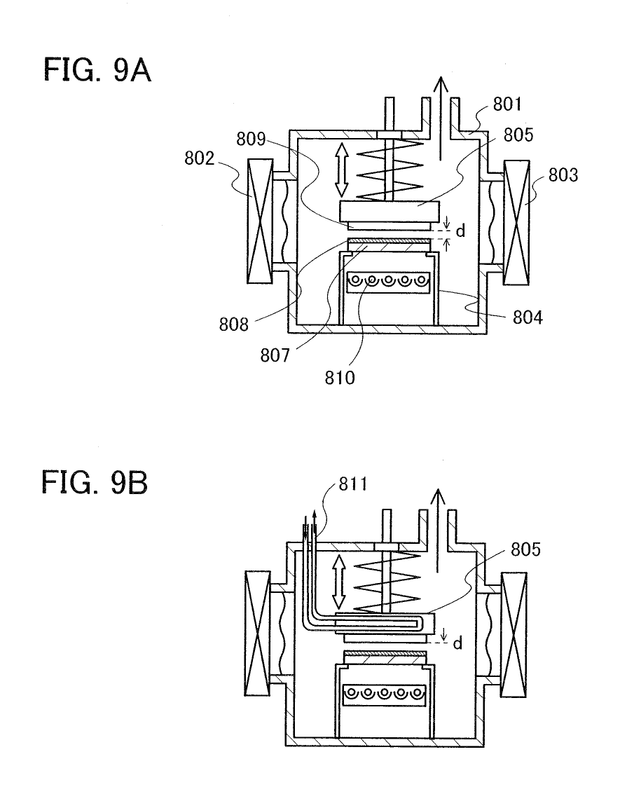

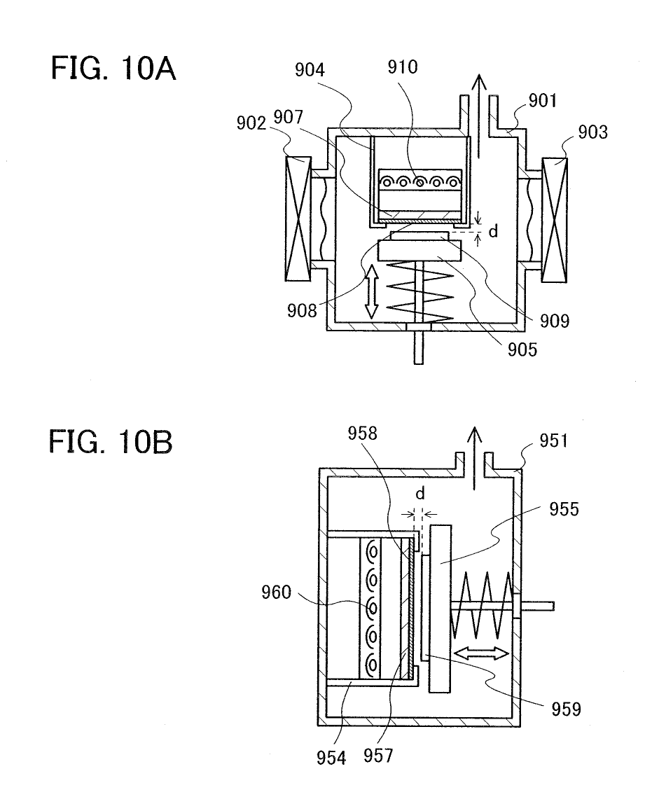

In this embodiment mode, examples of deposition apparatuses which enable manufacture of the light emitting device of the present invention are described. FIGS. 9A and 9B and FIGS. 10A and 10B show schematic cross-sectional views of deposition apparatuses of this embodiment mode.

In FIG. 9A, a deposition chamber 801 is a vacuum chamber and is connected to other treatment chambers via a first gate valve 802 and a second gate valve 803. The deposition chamber 801 at least includes a substrate supporting unit which is a first substrate supporting unit 804, a deposition target substrate supporting unit which is a second substrate supporting unit 805, and a light source 810.

First, in another deposition chamber, a material layer 808 is formed over a first substrate 807 which is a supporting substrate. In this embodiment mode, the first substrate 807 corresponds to the first substrate 200 shown in FIGS. 1A to 1C, and the material layer 808 corresponds to the first layer 202 containing the evaporation material. In this embodiment mode, as the first substrate 807, a square plate substrate which includes copper as its main component is used. For the material layer 808, a material which can be evaporated is used. Note that there is no particular limitation on the shape of the first substrate 807 as long as the first substrate 807 has the same area as or a larger area than a deposition target substrate. The material layer 808 can be formed by a dry method or a wet method, and in particular, a wet method is preferable. For example, a spin coating method, a printing method, an ink-jet method, or the like can be used.

The first substrate 807 is transported to the deposition chamber 801 from the other deposition chamber and is set on the substrate supporting unit. A second substrate 809 which is a deposition target substrate is fixed to the deposition target substrate supporting unit so that a surface of the first substrate 807, over which the material layer 808 is formed, faces a deposition target surface of the second substrate 809.

The second substrate supporting unit 805 is moved so that the distance between the first substrate 807 and the second substrate 809 becomes a distance d. Note that the distance d is defined as a distance between a surface of the material layer 808 which is formed over the first substrate 807 and a surface of the second substrate 809. In addition, in the case where some layer (e.g., a conductive layer which functions as an electrode or an insulating layer which functions as a partition wall) is formed on the second substrate 809, the distance d is defined as a distance between the surface of the material layer 808 over the first substrate 807 and the surface of the layer formed on the second substrate 809. Note that, in the case where the surface of the second substrate 809 or the surface of the layer formed on the second substrate 809 is uneven, the distance d is defined as the shortest distance between the surface of the material layer 808 over the first substrate 807 and the outermost surface of the second substrate 809 or the layer formed on the second substrate 809. In this embodiment mode, the distance d is 2 mm. If the second substrate 809 is hard like a quartz substrate and formed of a material which is unlikely to be deformed (warped, bent, or the like), the distance d can be shortened to 0 mm as the minimum distance. Although examples in which the deposition target substrate supporting unit is moved while the substrate supporting unit is fixed for controlling the distance between the substrates are shown in FIGS. 9A and 9B, a structure may also be employed in which the substrate supporting substrate is moved while the deposition target substrate supporting unit is fixed. Alternatively, both the substrate supporting unit and the deposition target substrate supporting unit may be moved. Note that FIG. 9A shows a cross section of a step in which the second substrate supporting unit 805 is moved so that the first substrate 807 and the second substrate 809 are disposed close to each other to have the distance d therebetween.

Alternatively, a structure may also be employed in which the substrate supporting unit and the deposition target substrate supporting unit are moved not only in a vertical direction but also in a horizontal direction and precise alignment is performed. In addition, the deposition chamber 801 may include an alignment mechanism such as CCD for precise alignment or measurement of the distance d. In addition, a sensor for measuring the temperature or humidity inside the deposition chamber 801, or the like may be provided.

The supporting substrate is irradiated with light from the light source 810. Accordingly, the material layer 808 over the supporting substrate is heated and sublimed in a short time, and thus an evaporation material is deposited on a deposition target surface (i.e., a lower flat surface) of the second substrate 809, which is placed so as to face the surface of the material layer 808. When the deposition apparatus shown in FIG. 9A is used, if the material layer 808 with a uniform thickness is formed over the first substrate 807 in advance, deposition of a film with high uniformity in thickness can be performed on the second substrate 809 without the use of any thickness monitor. A substrate is rotated in a conventional evaporation apparatus. In contrast, the deposition target substrate is fixed during deposition in the deposition apparatus shown in FIG. 9A; thus, this deposition apparatus is suitable for deposition to a large-area glass substrate that is easily broken. In addition, in the deposition apparatus in FIG. 9A, the supporting substrate is also stopped during deposition.

Note that it is preferable that the contact area of the light source 810 with the supporting substrate be large for uniform heating.

In order to reduce thermal effects on the material layer 808 formed over the supporting substrate due to heat from the light source on standby, an openable and closable shutter used for thermal insulation on standby (before an evaporation process) may be provided between the light source 810 and the first substrate 807 (supporting substrate).

The light source 810 may be a heating unit capable of uniform heating in a short time. For example, a laser or a lamp may be used.

For example, as the light source of laser light, one or more of the following lasers can be used: a gas laser such as an Ar laser, a Kr laser, or an excimer laser; a laser using as a medium a single-crystal YAG, YVO₄, forsterite (Mg₂SiO₄), YAlO₃, or GdVO₄ or a polycrystalline (ceramic) YAG, Y₂O₃, YVO₄, YAlO₃, or GdVO₄, which is doped with one or more of Nd, Yb, Cr, Ti, Ho, Er, Tm, and Ta as a dopant; a glass laser; a ruby laser; an alexandrite laser; a Ti:sapphire laser; a copper vapor laser; and a gold vapor laser. When a solid-state laser whose laser medium is solid is used, there are advantages in that a maintenance-free condition can be maintained for a long time and output is relatively stable.

Examples of lamps are as follows: a discharge lamp such as a flash lamp (e.g., a xenon flash lamp and a krypton flash lamp), a xenon lamp, or a metal halide lamp; and an exothermic lamp such as a halogen lamp or a tungsten lamp. A flash lamp is capable of repeatedly irradiating a large area with very high-intensity light in a short time (0.1 msec to 10 msec); thus, it can uniformly and efficiently heat the first substrate regardless of the area of the first substrate. In addition, heating of the first substrate can also be controlled by a change in length of a light emitting period. Furthermore, a flash lamp has a long lifetime and consumes less power on standby for light emission; thus, it can suppress the running cost. In addition, because a flash lamp is capable of rapid heating, a vertical movement mechanism, a shutter, and the like in the case of using a heater can be simplified. Thus, further reduction in the size of the deposition apparatus can be achieved.

Although FIG. 9A shows an example in which the light source 810 is provided in the deposition chamber 801, part of an inner wall of the deposition chamber may be made of a light-transmitting member and the light source 810 may be placed outside the deposition chamber. When the light source 810 is placed outside the deposition chamber 801, maintenance such as replacement of light bulbs of the light source 810 can be made easier.

FIG. 9B shows an example of a deposition apparatus provided with a mechanism for controlling the temperature of the second substrate 809. Note that components in FIG. 9B which are the same as those in FIG. 9A are denoted by the same reference numerals. In FIG. 9B, the second substrate supporting unit 805 includes a tube 811 through which a heat medium flows. A refrigerant flows through the tube 811 as a heat medium, whereby the second substrate supporting unit 805 can be used as a cold plate. Note that the tube 811 has a mechanism with which it can follow the vertical movement of the second substrate supporting unit 805. As the heat medium, for example, water, silicone oil, or the like can be used. Note that, although an example in which the tube 811 through which a refrigerant gas or a liquid refrigerant flows is used is described in this embodiment mode, the second substrate supporting unit 805 may be provided with a Peltier element or the like as a cooling unit. Alternatively, not a cooling unit but a heating unit may be provided. For example, a heat medium for heating may be made to flow through the tube 811.

The deposition apparatus shown in FIG. 9B is useful in stacking different kinds of material layers. For example, in the case where a first material layer has been formed on the second substrate, a second material layer having a higher evaporation temperature than the first material layer can be stacked on the first material layer In FIG. 9A, because the second substrate and the first substrate are disposed close to each other, the first material layer which has been formed on the second substrate may be sublimed. Thus, when the deposition apparatus shown in FIG. 9B is used, the second material layer can be stacked on the first material layer which has been formed on the second substrate while sublimation of the first material layer is suppressed using a cooling unit.

The second substrate supporting unit 805 may be provided with a heating unit such as a heater, in addition to the cooling unit. A unit for controlling (heating or cooling) the temperature of the second substrate 809 can prevent warpage or the like of the substrate.

Note that, although FIGS. 9A and 9B each show the example of the deposition apparatus employing a face-down system in which the deposition surface of the deposition target substrate faces downward, a deposition apparatus employing a face-up system as shown in FIG. 10A may be used.

In FIG. 10A, a deposition chamber 901 is a vacuum chamber and is connected to other treatment chambers via a first gate valve 902 and a second gate valve 903. The deposition chamber 901 at least includes a deposition target substrate supporting unit which is a second substrate supporting unit 905, a substrate supporting unit which is a first substrate supporting unit 904, and a light source 910.

A deposition process is as follows. First, in another deposition chamber, a material layer 908 is formed over a first substrate 907 which is a supporting substrate. In this embodiment mode, the first substrate 907 corresponds to the first substrate 200 shown in FIGS. 1A to 1C. There is no particular limitation on the shape of the first substrate 907 as long as the first substrate 907 has the same area as or a larger area than a deposition target substrate. The material layer 908 corresponds to the first layer 202 containing the evaporation material and contains plural kinds of materials which can be evaporated and have different evaporation temperatures. The material layer 908 can be formed by a dry method or a wet method, and in particular, a wet method is preferable. For example, a spin coating method, a printing method, an ink-jet method, or the like can be used.

The first substrate 907 is transported to the deposition chamber 901 from the other deposition chamber and is set on the substrate supporting unit. A second substrate 909 which is a deposition target substrate is fixed to the deposition target substrate supporting unit so that a surface of the first substrate 907, on which the material layer 908 is formed, faces a deposition target surface of the second substrate 909. As shown in FIG. 10A, this structure is an example of a face-up system in which the deposition target surface of the substrate faces upward. In the case of the face-up system, a large-area glass substrate which is easily bent is put on a flat stage, or the glass substrate is supported by a plurality of pins, whereby the substrate has no flexure, and thus a deposition apparatus can be realized with which a uniform thickness can be obtained over an entire surface of the substrate.

The second substrate supporting unit 905 is moved so that the distance between the first substrate 807 and the second substrate 809 becomes a distance d. Note that the distance d is defined as a distance between a surface of the material layer 908 which is formed on the first substrate 907 and a surface of the second substrate 909. In addition, in the case where some layer (e.g., a conductive layer which functions as an electrode or an insulating layer which functions as a partition wall) is formed over the second substrate 909, the distance d is defined as a distance between the surface of the material layer 908 on the first substrate 907 and the surface of the layer which is formed over the second substrate 909. Note that, in the case where the surface of the second substrate 909 or the surface of the layer formed over the second substrate 909 is uneven, the distance d is defined as the shortest distance between the surface of the material layer 908 on the first substrate 907 and the outermost surface of the second substrate 909 or the layer formed over the second substrate 909. Here, the distance d is 0.05 mm. Although the example in which the deposition target substrate supporting unit is moved while the substrate supporting unit is fixed is shown in FIG. 10A, a structure may also be employed in which the substrate supporting substrate is moved while the deposition target substrate supporting unit is fixed. Alternatively, both the substrate supporting unit and the deposition target substrate supporting unit may be moved to adjust the distance d.

As shown in FIG. 10A, the supporting substrate is irradiated with light from the light source 910 while the distance between the substrates is retained at the distance d. Note that it is preferable that the contact area of the light source 910 with the supporting substrate be large for uniform heating.

By irradiation of the supporting substrate with light from the light source 810, the material layer 908 on the supporting substrate is heated and sublimed in a short time, and thus an evaporation material is deposited on a deposition target surface (i.e., an upper flat surface) of the second substrate 909, which is placed so as to face the surface of the material layer 908. This makes it possible to realize a small-sized deposition apparatus the capacity of which is drastically smaller than that of a conventional evaporation apparatus which is a large-capacity chamber.

There is no particular limitation on the light source 910 as long as the light source 910 is a heating unit capable of uniform heating in a short time. For example, a laser or a lamp may be used. In the example shown in FIG. 10A, the light source 910 is fixed above the second substrate and a film is deposited on an upper surface of the second substrate 909 immediately after the light source 910 emits light.

Note that, although FIGS. 9A and 9B and FIG. 10A each show the example of the deposition apparatus employing a system in which substrates are arranged horizontally, a deposition apparatus employing a system in which substrates are arranged vertically as shown in FIG. 10B can also be used.

In FIG. 10B, a deposition chamber 951 is a vacuum chamber. The deposition chamber 951 at least includes a substrate supporting unit which is a first substrate supporting unit 954, a deposition target substrate supporting unit which is a second substrate supporting unit 955, and a light source 960.

Although not shown, the deposition chamber 951 is connected to a first transport chamber to and from which a deposition target substrate is transported while being placed vertically. The deposition chamber 951 is also connected to a second transport chamber to and from which a supporting substrate is transported while being placed vertically, which is also not shown. In this specification, vertical arrangement of a substrate refers to placement of a substrate in which a substrate surface makes a right angle or about a right angle (ranging from 70° to 110°) with a horizontal surface. Because a large-area glass substrate or the like is easy to bend, it is desirably transported with the vertical arrangement.

A lamp is more suitable than a laser as the light source 960 for heating of a large-area glass substrate.

A deposition process is as follows. First, in another deposition chamber, a material layer 958 is formed over a first substrate 957 which is a supporting substrate. Note that the first substrate 957 corresponds to the first substrate 200 shown in FIGS. 1A to 1C, and the material layer 958 corresponds to the first layer 202 containing the evaporation material.

Next, the first substrate 957 is transported to the deposition chamber 951 from the other deposition chamber and is set on the substrate supporting unit. A second substrate 959 is fixed to the deposition target substrate supporting unit so that a surface of the first substrate 957, over which the material layer 958 is formed, faces a deposition target surface of the second substrate 959.

Next, the supporting substrate is irradiated with light from the light source 960 and is rapidly heated while the distance between the substrates is retained at the distance d. When the supporting substrate is rapidly heated, the material layer 958 over the supporting substrate is heated and sublimed in a short time by indirect heat conduction, and thus an evaporation material is deposited on the deposition target surface of the second substrate 959, which is the deposition target substrate placed to face the supporting substrate. This makes it possible to realize a small-sized deposition apparatus the capacity of which is drastically smaller than that of a conventional evaporation apparatus which is a large-capacity chamber.

A plurality of deposition apparatuses described in this embodiment mode may be provided, whereby a multi-chamber manufacturing apparatus can be obtained. It is needless to say that a deposition apparatus of another film formation method can be combined therewith. Furthermore, a plurality of deposition apparatuses described in this embodiment mode can be disposed in series, whereby an in-line manufacturing apparatus can be obtained.

The use of such a deposition apparatus makes it possible to manufacture the light emitting device of the present invention. In the present invention, an evaporation source can be easily prepared by a wet method. In addition, because the evaporation source is evaporated as it is, a thickness monitor is not needed. Therefore, the whole deposition process can be automated, and thus throughput can be improved. Moreover, evaporation materials can be prevented from being attached to an inner wall of a deposition chamber, and thus maintenance of the deposition apparatus can be made easier.

Application of the present invention makes it easy to form a layer containing an evaporation material for forming a light emitting element and to manufacture a light emitting device including the light emitting element. Application of the present invention also makes it possible to form a flat even film. Application of the present invention facilitates patterning of a light emitting layer; thus, it also facilitates manufacture of a light emitting device. In addition, a precise pattern can be formed; thus, a high-definition light emitting device can be obtained. Furthermore, by application of the present invention, not only a laser but also a lamp heater or the like which is inexpensive but provides a large amount of heat can be used as a light source. Accordingly, manufacturing cost of a light emitting device can be reduced.

Note that this embodiment mode can be appropriately combined with any of the other embodiment modes described in this specification.

### Embodiment Mode 5

In this embodiment mode, an example of a deposition apparatus which enables manufacture of the light emitting device of the present invention is described.

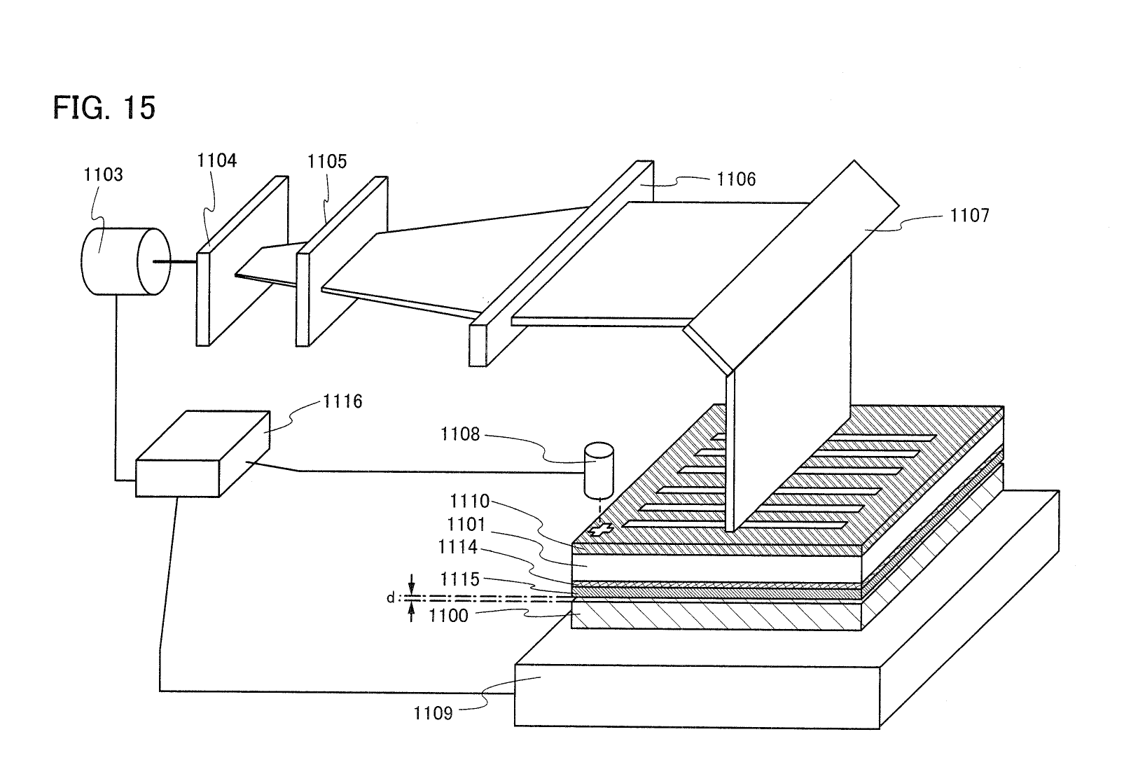

FIG. 15 is a perspective view showing an example of a deposition apparatus using a laser. A laser beam emitted is outputted from a laser device 1103 (a YAG laser device, an excimer laser device, or the like); the laser beam is transmitted through a first optical system 1104 for changing a beam shape into a rectangular shape, a second optical system 1105 for shaping a beam, and a third optical system 1106 for collimating a beam; and an optical path of the laser beam is bended to a direction perpendicular to an evaporation donor substrate 1101 by using a reflecting mirror 1107. Then, the evaporation donor substrate is irradiated with the laser beam.

A material which can withstand irradiation with laser light is used for a reflective layer 1110 having openings.

The shape of a laser spot with which layers (a reflective layer and a light absorption layer) provided over the evaporation donor substrate are irradiated is desirably rectangular or linear. Specifically, the shape may be a rectangle having a shorter side of 1 mm to 5 mm and a longer side of 10 mm to 50 mm. Furthermore, in the case of using a large-area substrate, a laser spot preferably has a longer side of 20 cm to 100 cm in order to shorten processing time. Moreover, a plurality of laser devices and optical systems shown in FIG. 15 may be provided to process a large-area substrate in a short time. Specifically, laser beams may be emitted from the plurality of laser devices so that the laser beams are used to process separate areas of a substrate.

Note that FIG. 15 shows an example, and there is no particular limitation on positional relationship between each optical system and electro-optical element placed along the path of a laser beam. For example, a reflective mirror is not necessarily needed if the laser device 1103 is placed above the evaporation donor substrate 1101 so that a laser beam is emitted from the laser device 1103 in a direction perpendicular to a principle plane of the evaporation donor substrate 1101. Furthermore, each optical system may be a condenser lens, a beam expander, a homogenizer, a polarizer, or the like, and these may be combined. Further, each optical system may be combined with a slit.

By appropriate two-dimensional scanning of an irradiation surface by laser irradiation, a wide area of the substrate is irradiated. The scanning is achieved by relative movement between a laser light irradiation region and the substrate. Here, the scanning is performed with a moving unit (not shown) for moving a substrate stage 1109 which holds the substrate in X and Y directions.

A control device 1116 is preferably interlocked such that it can also control the moving unit which moves the substrate stage 1109 in the X and Y directions. Furthermore, the control device 1116 is preferably interlocked such that it can also control the laser device 1103. Moreover, the control device 1116 is preferably interlocked with a position alignment mechanism which has an image pickup element 1108 for recognizing a position marker.

The position alignment mechanism aligns the evaporation donor substrate 1101 and a deposition target substrate 1100 with each other.

The evaporation donor substrate 1101 which is irradiated with laser light is provided with the reflective layer 1110 on a side subjected to laser irradiation and provided with a light absorption layer 1114 and a material layer 1115 which are stacked in this order on the other side. For the light absorption layer 1114, a heat-resistant metal is preferably used, and for example, tungsten, tantalum, or the like is used.

The evaporation donor substrate 1101 and the deposition target substrate 1100 are disposed close to each other so that they face each other at a distance d of 0 mm to 0.05 mm, preferably, 0 mm to 0.03 mm. When the deposition target substrate 1100 is provided with an insulator which serves as a partition wall, the insulator and the material layer 1115 may be disposed in contact with each other.

When deposition is performed with use of the deposition apparatus shown in FIG. 15, at least the evaporation donor substrate 1101 and the deposition target substrate 1100 are disposed in a vacuum chamber. Alternatively, all of the components shown in FIG. 15 may be placed in a vacuum chamber.

Although FIG. 15 shows an example of the deposition apparatus employing a face-up system in which the deposition surface of the deposition target substrate 1100 faces upward, a deposition apparatus employing a face-down system may be used. When the deposition target substrate 1100 is a large-area substrate, a so-called vertical arrangement apparatus may also be employed in which a principal plane of the deposition target substrate 1100 is arranged perpendicular to a horizontal plane in order to suppress distortion of the center of the substrate due to its own weight.

When a cooling unit for cooling the deposition target substrate 1100 is provided, a flexible substrate such as a plastic substrate can be used as the deposition target substrate 1100.

A plurality of deposition apparatuses described in this embodiment mode may be provided, whereby a multi-chamber manufacturing apparatus can be obtained. It is needless to say that a deposition apparatus of another film formation method can be combined therewith. Furthermore, a plurality of deposition apparatuses described in this embodiment mode can be disposed in series, whereby an in-line manufacturing apparatus can be obtained.

The use of such a deposition apparatus makes it possible to manufacture the light emitting device of the present invention. In the present invention, an evaporation source can be easily prepared by a wet method. In addition, because the evaporation source is evaporated as it is, a thickness monitor is not needed. Therefore, the whole deposition process can be automated, and thus throughput can be improved. Moreover, evaporation materials can be prevented from being attached to an inner wall of a deposition chamber, and thus maintenance of the deposition apparatus can be made easier.

Application of the present invention makes it easy to form a layer containing an evaporation material for forming a light emitting element and to manufacture a light emitting device including the light emitting element. Application of the present invention also makes it possible to form a flat even film. Application of the present invention facilitates patterning of a light emitting layer; thus, it also facilitates manufacture of a light emitting device. In addition, a precise pattern can be formed; thus, a high-definition light emitting device can be obtained. Furthermore, by application of the present invention, not only a laser but also a lamp heater or the like which is inexpensive but provides a large amount of heat can be used as a light source. Accordingly, manufacturing cost of a light emitting device can be reduced.

Note that this embodiment mode can be appropriately combined with any of the other embodiment modes described in this specification.

### Embodiment Mode 6

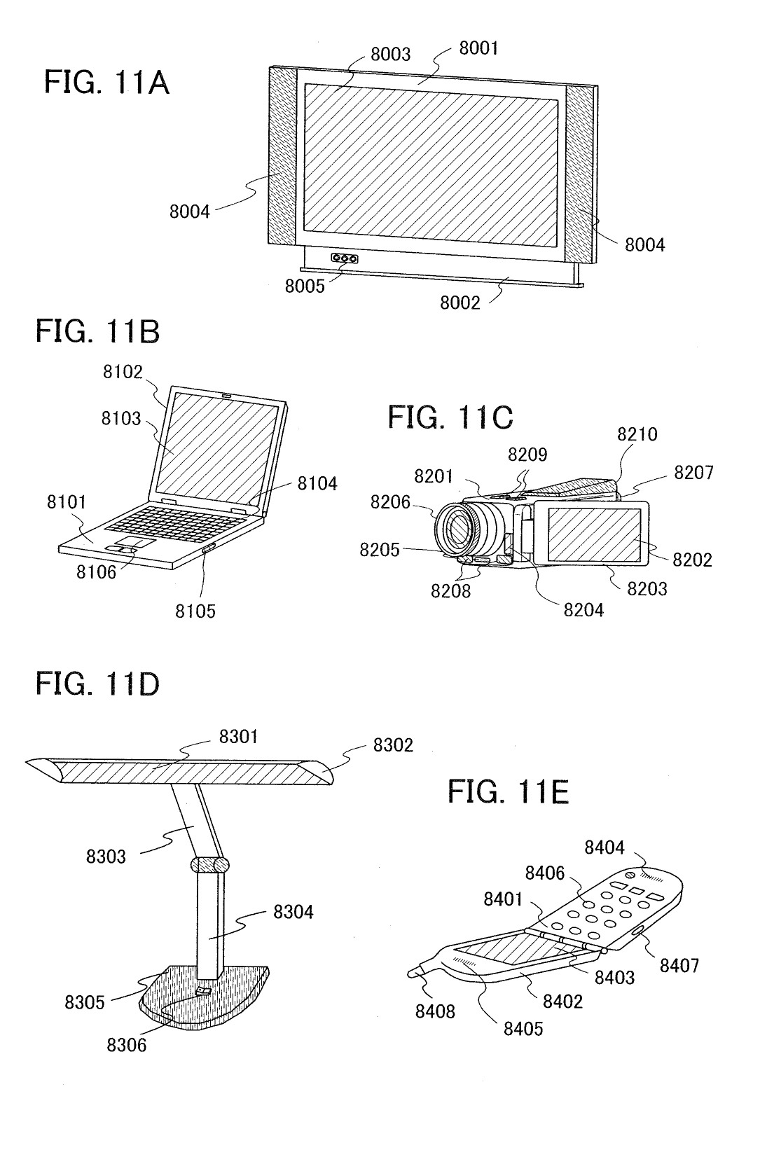

In this embodiment mode, various electronic devices each of which is completed using the light emitting device manufactured by application of the present invention are described with reference to FIGS. 11A to 11E.

Examples of electronic devices manufactured using the light emitting device of the present invention include a television, a camera such as a video camera or a digital camera, a goggle type display (head mounted display), a navigation system, an audio reproducing device (such as a car audio and an audio component), a notebook computer, a game machine, a portable information terminal (such as a mobile computer, a cellular phone, a portable game machine, and an electronic book), an image reproducing device provided with a recording medium (specifically, a device for reproducing a recording medium such as a digital video disc (DVD) and having a display device for displaying the reproduced image), a lighting device, and the like. Specific examples of these electronic devices are shown in FIGS. 11A to 11E.

FIG. 11A shows a display device, which includes a chassis 8001, a support 8002, a display portion 8003, a speaker portion 8004, a video input terminal 8005, and the like. The display device is manufactured using a light emitting device, which is formed using the present invention, in the display portion 8003. Note that the display device includes all devices for displaying information such as for a personal computer, for receiving TV broadcasting, and for displaying an advertisement. Because throughput can be improved by application of the present invention, productivity in manufacturing the display device can be improved. In addition, because loss of materials in manufacturing the display device can be reduced, manufacturing cost can be reduced and an inexpensive display device can be provided.

FIG. 11B shows a computer, which includes a main body 8101, a chassis 8102, a display portion 8103, a keyboard 8104, an external connecting port 8105, a mouse 8106, and the like. The computer is manufactured using a light emitting device, which is formed using the deposition apparatus of the present invention, in the display portion 8103. Because throughput can be improved by application of the present invention, productivity in manufacturing the display device can be improved. In addition, because loss of materials in manufacturing the display device can be reduced, manufacturing cost can be reduced and an inexpensive computer can be provided.

FIG. 11C shows a video camera, which includes a main body 8201, a display portion 8202, a chassis 8203, an external connecting port 8204, a remote control receiving portion 8205, an image receiving portion 8206, a battery 8207, an audio input portion 8208, an operation key 8209, an eye piece portion 8210, and the like. The video camera is manufactured using a light emitting device, which is formed using the deposition apparatus of the present invention, in the display portion 8202. Because throughput can be improved by application of the present invention, productivity in manufacturing the display device can be improved. In addition, because loss of materials in manufacturing the display device can be reduced, manufacturing cost can be reduced and an inexpensive video camera can be provided.

FIG. 11D shows a desk lamp, which includes a lighting portion 8301, a shade 8302, an adjustable arm 8303, a support 8304, a base 8305, and a power supply switch 8306. The desk lamp is manufactured using a light emitting device, which is formed using the deposition apparatus of the present invention, in the lighting portion 8301. Note that a lamp includes a ceiling light, a wall light, and the like in its category. Because throughput can be improved by application of the present invention, productivity in manufacturing the light emitting device can be improved. In addition, because loss of materials in manufacturing the light emitting device can be reduced, manufacturing cost can be reduced and an inexpensive desk lamp can be provided.

FIG. 11E shows a cellular phone, which includes a main body 8401, a chassis 8402, a display portion 8403, an audio input portion 8404, an audio output portion 8405, an operation key 8406, an external connecting port 8407, an antenna 8408, and the like. The cellular phone is manufactured using a light emitting device, which is formed using the deposition apparatus of the present invention, in the display portion 8403. Because throughput can be improved by application of the present invention, productivity in manufacturing the display device can be improved. In addition, because loss of materials in manufacturing the display device can be reduced, manufacturing cost can be reduced and an inexpensive cellular phone can be provided.

As described above, an electronic device or a lighting device can be obtained by using the light emitting device of the present invention. The range of application of the light emitting device of the present invention is so wide that the light emitting device can be applied to electronic devices of various fields.

Note that this embodiment mode can be appropriately combined with any of the other embodiment modes described in this specification.

### Embodiment 1

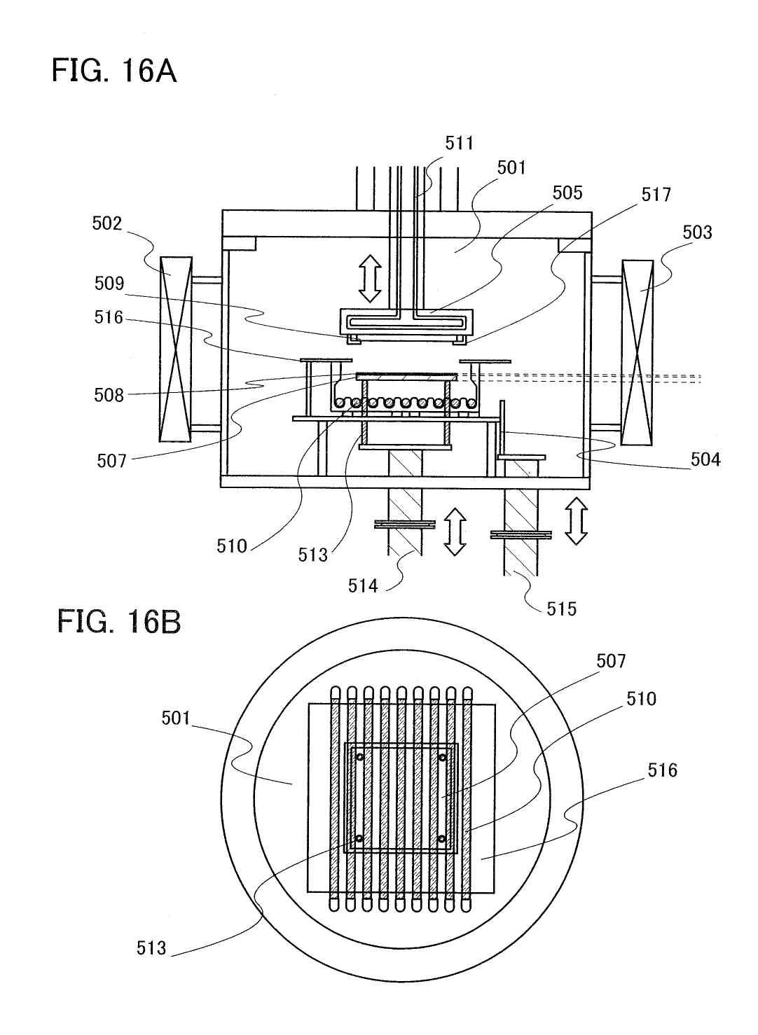

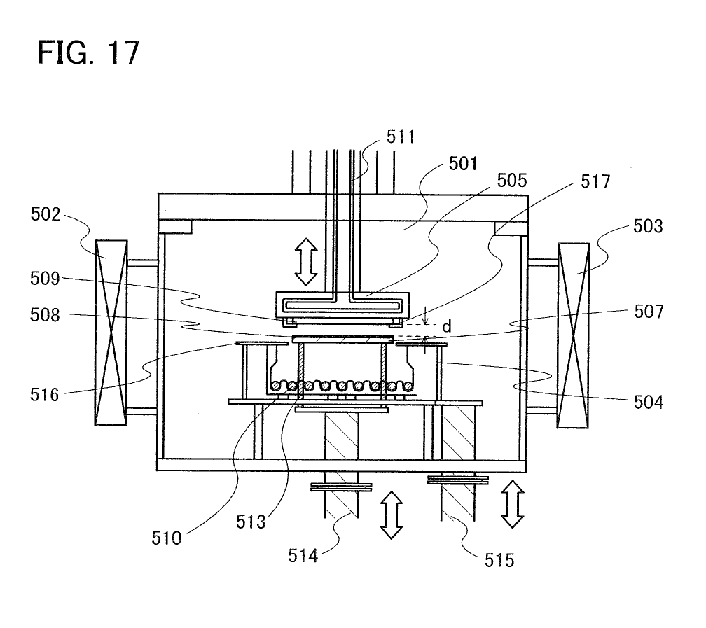

In this embodiment, an example of a deposition apparatus which enables manufacture of the light emitting device of the present invention is described with reference to FIGS. 16A and 16B and FIG. 17. Note that FIG. 16A is a cross-sectional view of the deposition apparatus, and 16B is a top view of the deposition apparatus.

In FIGS. 16A and 16B, a deposition chamber 501 is a vacuum chamber and is connected to other treatment chambers via a first gate valve 502 and a second gate valve 503. The deposition chamber 501 includes a substrate supporting unit 513 which is a first substrate supporting unit, a deposition target substrate supporting unit 505 which is a second substrate supporting unit, and a halogen lamp 510 as a light source. The halogen lamp is capable of rapid heating. The halogen lamp can also control heating of the first substrate by a change in length of a period in which light is emitted. In addition, because the halogen lamp 510 is capable of rapid heating, a vertical movement mechanism, a shutter, and the like in the case of using a heater can be simplified. Thus, further reduction in the size of the deposition apparatus can be achieved.

First, in another deposition chamber, a material layer 508 is formed over a first substrate 507 which is a supporting substrate. In this embodiment, a glass substrate over which a titanium film is deposited is used as the first substrate 507. Titanium can efficiently absorb light at about 1100 nm to 1200 nm corresponding to the emission wavelength of a halogen lamp which is used as a light source; thus the material layer 508 formed over the titanium film can be efficiently heated. For the material layer 508, a material which can be evaporated is used. Note that, in this embodiment, a substrate which has the same area as the deposition target substrate is used as the first substrate 507. Furthermore, the material layer 508 is formed by a wet method in this embodiment.

As indicated by dotted lines in FIG. 16A, the first substrate 507 is transported to the deposition chamber 501 from the other deposition chamber and is set on the substrate supporting unit 513. At the time of the transport, a reflector shutter 504 is opened with a movable unit 515, and the first substrate 507 is set on the substrate supporting unit 513 through the opened reflector shutter 504. The first substrate 507 is fixed to the substrate supporting unit 513 so that a surface of the first substrate 507, over which the material layer 508 is formed, faces a deposition target surface of a second substrate 509 which is a deposition target substrate.

Note that it is preferable that the deposition chamber 501 be evacuated to a vacuum. Specifically, the deposition chamber is evacuated to a vacuum of 5×10⁻³ Pa or less, preferably from about 10⁻⁴ Pa to 10⁻⁶ Pa. As a vacuum evacuation unit which is connected to the deposition chamber, an oil-free dry pump is used to perform vacuum evacuation of from the atmospheric pressure to a pressure on the order of 1 Pa, whereas a magnetic floating turbo molecular pump or a compound molecular pump is used to perform vacuum evacuation of a pressure lower than the above-described range. This prevents contamination by an organic substance, mainly such as oil, from the evacuation unit. An inner wall surface is subjected to mirror surface treatment by electrolytic polishing to reduce its surface area, thereby preventing gas discharge.

The second substrate 509 is fixed to the deposition target substrate supporting unit 505 with a fixing unit 517. The deposition target substrate supporting unit 505 includes a tube 511 through which a heat medium flows. The tube 511 through which a heat medium flows enables the deposition target substrate supporting unit 505 to maintain an appropriate temperature. For example, cold water may flow through the tube 511 to cool the deposition target substrate or warm water may flow to heat it.

Next, as shown in FIG. 17, the first substrate 507 and the second substrate 509 are disposed close to each other so that the distance therebetween becomes a distance d. Note that the distance d is defined as a distance between a surface of the material layer 508 which is formed over the first substrate 507 and a surface of the second substrate 509. In addition, in the case where some layer (e.g., a conductive layer which functions as an electrode or an insulating layer which functions as a partition wall) is formed on the second substrate 509, the distance d is defined as a distance between the surface of the material layer 508 over the first substrate 507 and the surface of the layer which is formed on the second substrate 509. Note that, in the case where the surface of the second substrate 509 or the surface of the layer formed on the second substrate 509 is uneven, the distance d is defined as the shortest distance between the surface of the material layer 508 over the first substrate 507 and the outermost surface of the second substrate 509 or the layer formed on the second substrate 509. In this embodiment, the distance d between the substrates is 0.05 mm.

In the deposition apparatus described in this embodiment, the distance between the substrates is controlled by up-and-down movement of the deposition target substrate supporting unit 505 or by up-and-down movement of substrate lift pins, which constitute the substrate supporting unit 513, with the first substrate 507 lifted up. The substrate lift pins made of quartz are moved up and down by a movable unit 514 to lift up the first substrate 507.

Note that, in this embodiment, the distance between the first substrate 507 (supporting substrate) and the halogen lamp 510 which is a light source is set to be 50 mm on standby (before an evaporation process), in order to reduce thermal effects on the material layer 508 formed over the supporting substrate due to heat from the light source on standby.

Heat treatment is performed using the halogen lamp 510 while the distance between the substrates is retained at the distance d. First, for preheating, an output of the halogen lamp 510 is maintained at a temperature of 60° C. for 15 seconds. The preheating stabilizes the output of the halogen lamp 510. After that, heat treatment is performed. In the heat treatment, a temperature of 500° C. to 800° C. is maintained for 7 to 15 seconds. Because the length of time it takes for the heat treatment varies depending on an evaporation material, the length is appropriately set. Note that a reflector 516 and the reflector shutter 504 are provided so that the whole deposition chamber is not heated due to scattering of light from the halogen lamp 510.

The titanium film formed over the first substrate 507 is heated by absorbing light from the halogen lamp 510; accordingly, the material layer 508 over the titanium film is heated and sublimed, and thus an evaporation material is deposited on a deposition target surface (i.e., a lower flat surface) of the second substrate 509, which is placed so as to face the surface of the material layer 508. When the deposition apparatus shown in FIGS. 16A and 16B and FIG. 17 is used, if the material layer 508 with a uniform thickness is formed over the first substrate 507 in advance, deposition of a film with high uniformity in thickness can be performed on the second substrate 509 without the use of any thickness monitor. A substrate is rotated in a conventional evaporation apparatus. In contrast, the deposition target substrate is fixed during deposition in the deposition apparatus shown in FIGS. 16A and 16B and FIG. 17; thus, this deposition apparatus is suitable for deposition to a large-area glass substrate that is easily broken. In addition, in the deposition apparatus in FIGS. 16A and 16B and FIG. 17, the supporting substrate is also stopped during deposition.

The use of the deposition apparatus of this embodiment makes it possible to manufacture the light emitting device of the present invention. In the present invention, an evaporation source can be easily prepared by a wet method. In addition, because the evaporation source is evaporated as it is, a thickness monitor is not needed. Therefore, the whole deposition process can be automated, and thus throughput can be improved. Moreover, evaporation materials can be prevented from being attached to an inner wall of a deposition chamber, and thus maintenance of the deposition apparatus can be made easier.

### Embodiment 2

In this embodiment, reflectances of materials used for a reflective layer and a light absorption layer are described.

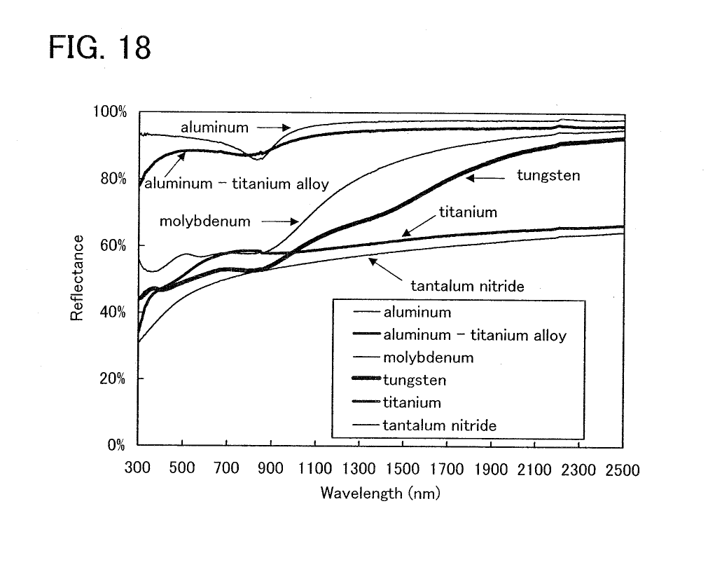

An aluminum film, an aluminum-titanium alloy film, a molybdenum film, a tantalum nitride film, a titanium film, and a tungsten film were formed over glass substrates by a sputtering method. These metal materials can be suitably used in the present invention due to their excellent heat resistance. The thickness of each metal film is 400 nm. FIG. 18 shows reflectances of the metal films formed.

As shown in FIG. 18, the aluminum film and the aluminum-titanium alloy film each have a reflectance of 85% or higher in an infrared region (at a wavelength of 800 nm to 2500 nm). Therefore, the aluminum film and the aluminum-titanium alloy film can be used as reflective layers. In particular, each of them has a reflectance of 90% or higher at a wavelength ranging from 900 nm to 2500 nm; thus, they are suitable for use as reflective layers.

On the other hand, the titanium film and the tantalum nitride film each have a reflectance of 67% or lower in the infrared region (at a wavelength of 800 nm to 2500 nm). Therefore, the titanium film and the tantalum nitride film can be used as light absorption layers. In particular, each of them has a reflectance of 60% or lower at a wavelength of 800 nm to 1250 nm; thus, they are suitable for use as light absorption layers.

Furthermore, the molybdenum film and the tungsten film each have a reflectance of 60% or lower for light at a wavelength of 800 nm to 900 nm; thus, they are suitable for use as light absorption layers. In addition, the molybdenum film and the tungsten film each have a reflectance of 85% or higher for light at a wavelength of 2000 nm to 2500 nm; thus, they can be used as reflective layers.

### Embodiment 3

In this embodiment, thickness and reflectance of an aluminum film are described.

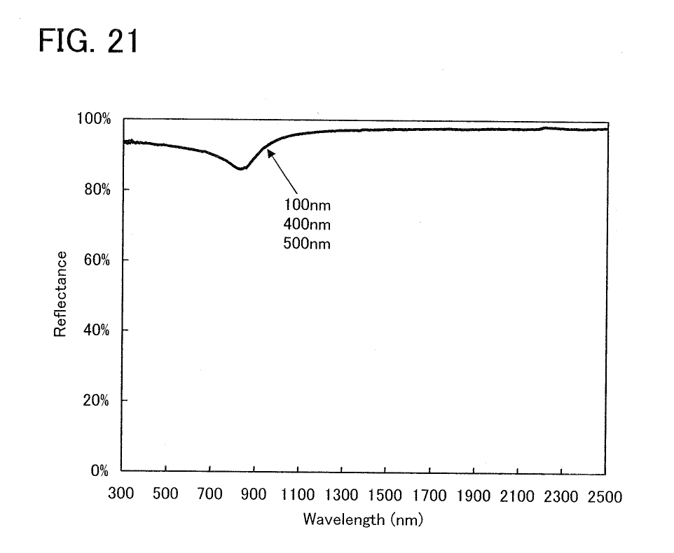

Aluminum films were formed over glass substrates by a sputtering method. The aluminum films have thicknesses of 100 nm, 400 nm, and 500 nm. FIG. 21 shows reflectances of the films formed.

As shown in FIG. 21, the films having thicknesses of 100 nm, 400 nm, and 500 nm have similar reflectances, each of which has a reflectance of 85% or higher in the infrared region (at a wavelength of 800 nm to 2500 nm). In particular, at wavelengths ranging from 900 nm to 2500 nm, each of the films has a reflectance of 90% or higher.

Transmittances of the films formed were also measured. The results show that each of the films having thicknesses of 100 nm, 400 nm, and 500 nm has a transmittance of about 0% and transmits almost no light in the infrared region (at a wavelength of 800 nm to 2500 nm).

Accordingly, it can be seen that an aluminum film is suitable for use as a reflective layer. It can also be seen that an aluminum film is suitable for use as a reflective layer when having a thickness of 100 nm or more.

### Embodiment 4

In this embodiment, thickness and reflectance of a titanium film are described.

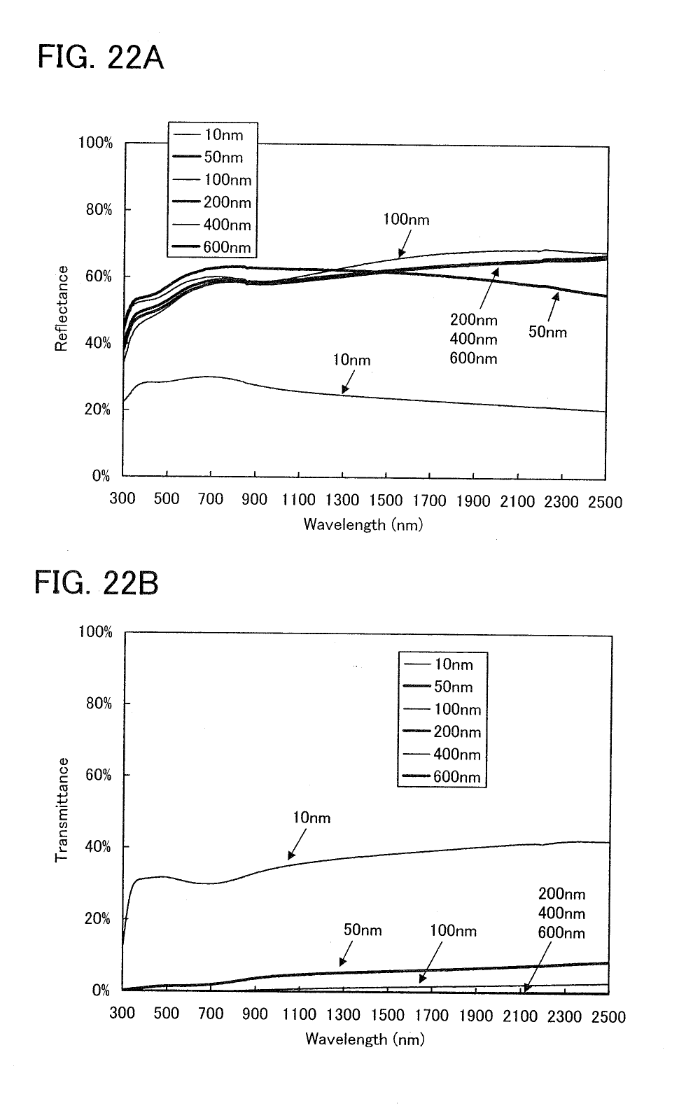

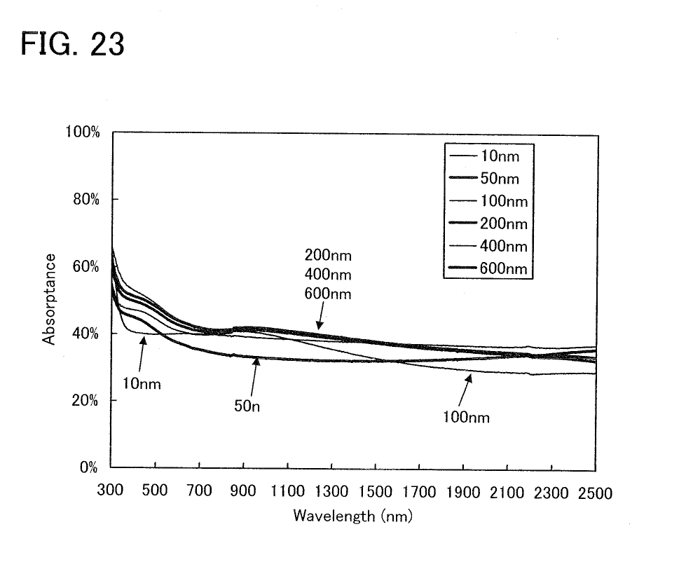

Titanium films were formed over glass substrates by a sputtering method. The titanium films have thicknesses of 10 nm, 50 nm, 100 nm, 200 nm, 400 nm, and 600 nm. FIG. 22A shows reflectances of the films formed; FIG. 22B, transmittances; and FIG. 23, absorptances. Note that the absorptances shown in FIG. 23 are each obtained by subtraction of a measured reflectance and a measured transmittance from 100% assuming that irradiation light is 100%.

As shown in FIG. 22A, the films having thicknesses of 200 nm, 400 nm, and 600 nm have similar reflectances, each of which has a reflectance of 67% or lower in the infrared region (at a wavelength of 800 nm to 2500 nm). It can also been seen as shown in FIG. 22B that each of the films transmits almost no light at wavelengths ranging from 300 nm to 2500 nm. Therefore, a titanium film can be used as a light absorption layer when having a thickness of 200 nm or more.

The films having thicknesses of 10 nm, 50 nm, and 100 nm each have a low reflectance, but they each have a transmittance of 2% or higher as shown in FIG. 22B. Therefore, each of the layers may transmit irradiation light when used as a light absorption layer. Therefore, when a titanium film is used as a light absorption layer, it is preferable that the titanium film have a thickness of 100 nm or more.

As shown in FIG. 23, the titanium films having thicknesses of 200 nm, 400 nm, and 600 nm each have an absorptance of 30% or higher.

Accordingly, it can be seen that a titanium film having a thickness of 200 nm to 600 nm is suitable for use as a light absorption layer.

This application is based on Japanese Patent Application serial no. 2007-237493 filed with Japan Patent Office on Sep. 13, 2007, the entire contents of which are hereby incorporated by reference.

What is claimed is:

1. A manufacturing method of a light emitting device, comprising the steps of:
forming an evaporation material over a second surface of a first substrate so as to cover a light absorption layer, the first substrate being provided with a reflective layer having an opening over a first surface facing the second surface; and
performing light irradiation from a side of the first surface of the first substrate in a state where the second surface of the first substrate is disposed close to a surface of a second substrate thereby making irradiation light absorbed by a portion of the light absorption layer overlapping with the opening in the reflective layer to heat the evaporation material and to attach the evaporation material to the surface of the second substrate.

2. The manufacturing method of a light emitting device according to claim 1, wherein the light absorption layer is formed in an island shape to overlap with the opening in the reflective layer.

3. The manufacturing method of a light emitting device according to claim 1, wherein the irradiation light is infrared light.

4. The manufacturing method of a light emitting device according to claim 1, wherein the reflective layer has a reflectance of 85% or more for the irradiation light.

5. The manufacturing method of a light emitting device according to claim 1, wherein the reflective layer contains one of aluminum, silver, gold, platinum, copper, an alloy containing aluminum, and an alloy containing silver.

6. The manufacturing method of a light emitting device according to claim 1, wherein the light absorption layer has a reflectance of 60% or less for the irradiation light.

7. The manufacturing method of a light emitting device according to claim 1, wherein a thickness of the light absorption layer is 200 nm to 600 nm.

8. The manufacturing method of a light emitting device according to claim 1, wherein the light absorption layer contains one of tantalum nitride, titanium, and carbon.

9. The manufacturing method of a light emitting device according to claim 1, wherein the evaporation material is attached to the second surface of the first substrate by a wet method.

10. The manufacturing method of a light emitting device according to claim 1, wherein the evaporation material is an organic compound.

11. The manufacturing method of a light emitting device according to claim 1, wherein the evaporation material is one of a light emitting material and a carrier transporting material.

12. A manufacturing method of a light emitting device, comprising the steps of:
forming a reflective layer having an opening over a first surface of a first substrate;
forming a light absorption layer over a second surface facing the first surface of the first substrate;
forming an evaporation material over the second surface of the first substrate so as to cover the light absorption layer; and
performing light irradiation from a side of the first surface of the first substrate in a state where the second surface of the first substrate is disposed close to a surface of a second substrate thereby making irradiation light absorbed by a portion of the light absorption layer overlapping with the opening in the reflective layer to heat the evaporation material and to attach the evaporation material to the surface of the second substrate.

13. The manufacturing method of a light emitting device according to claim 12, wherein the light absorption layer is formed in an island shape to overlap with the opening in the reflective layer.

14. The manufacturing method of a light emitting device according to claim 12, wherein the irradiation light is infrared light.

15. The manufacturing method of a light emitting device according to claim 12, wherein the reflective layer has a reflectance of 85% or more for the irradiation light.

16. The manufacturing method of a light emitting device according to claim 12, wherein the reflective layer contains one of aluminum, silver, gold, platinum, copper, an alloy containing aluminum, and an alloy containing silver.

17. The manufacturing method of a light emitting device according to claim 12, wherein the light absorption layer has a reflectance of 60% or less for the irradiation light.

18. The manufacturing method of a light emitting device according to claim 12, wherein a thickness of the light absorption layer is 200 nm to 600 nm.

19. The manufacturing method of a light emitting device according to claim 12, wherein the light absorption layer contains one of tantalum nitride, titanium, and carbon.

20. The manufacturing method of a light emitting device according to claim 12, wherein the evaporation material is attached to the second surface of the first substrate by a wet method.

21. The manufacturing method of a light emitting device according to claim 12, wherein the evaporation material is an organic compound.

22. The manufacturing method of a light emitting device according to claim 12, wherein the evaporation material is one of a light emitting material and a carrier transporting material.

23. A manufacturing method of a light emitting device, comprising the steps of:
forming an evaporation material over a second surface of a first substrate so as to cover a light absorption layer, the first substrate being provided with a reflective layer having an opening over a first surface opposite to the second surface;
forming a first electrode over a second substrate;
performing light irradiation from a side of the first surface of the first substrate in a state where the second surface of the first substrate is disposed close to a surface of the second substrate thereby making irradiation light absorbed by a portion of the light absorption layer overlapping with the opening in the reflective layer to heat the evaporation material and to attach the evaporation material to the surface of the second substrate, after forming the first electrode; and
forming a second electrode over the surface of the second substrate, after performing light irradiation.

24. The manufacturing method of a light emitting device according to claim 23, wherein the light absorption layer is formed in an island shape to overlap with the opening in the reflective layer.

25. The manufacturing method of a light emitting device according to claim 23, wherein the irradiation light is infrared light.

26. The manufacturing method of a light emitting device according to claim 23, wherein the reflective layer has a reflectance of 85% or more for the irradiation light.

27. The manufacturing method of a light emitting device according to claim 23, wherein the reflective layer contains one of aluminum, silver, gold, platinum, copper, an alloy containing aluminum, and an alloy containing silver.

28. The manufacturing method of a light emitting device according to claim 23, wherein the light absorption layer has a reflectance of 60% or less for the irradiation light.

29. The manufacturing method of a light emitting device according to claim 23, wherein a thickness of the light absorption layer is 200 nm to 600 nm.

30. The manufacturing method of a light emitting device according to claim 23, wherein the light absorption layer contains one of tantalum nitride, titanium, and carbon.

31. The manufacturing method of a light emitting device according to claim 23, wherein the evaporation material is attached to the second surface of the first substrate by a wet method.

32. The manufacturing method of a light emitting device according to claim 23, wherein the evaporation material is an organic compound.

33. The manufacturing method of a light emitting device according to claim 23, wherein the evaporation material is one of a light emitting material and a carrier transporting material.

34. The manufacturing method of a light emitting device according to claim 23, wherein the first electrode is a pixel electrode.

35. An evaporation donor substrate comprising:
a reflective layer having an opening over a first surface; and
a light absorption layer over a second surface facing the first surface.

36. The evaporation donor substrate according to claim 35, wherein the light absorption layer is formed in an island shape to overlap with the opening in the reflective layer.

37. The evaporation donor substrate according to claim 35, wherein an evaporation material is attached to the light absorption layer.

38. The evaporation donor substrate according to claim 37, wherein the evaporation material is an organic compound.
